(19) United States
(12) Patent Application Publication
(10) Pub. No.: US 2023/0061915 A1
(43) Pub. Date: Mar. 2, 2023

(54) SEMICONDUCTOR LIGHT EMITTING DEVICE FOR A DISPLAY PANEL, A SUBSTRATE STRUCTURE FOR A DISPLAY PANEL, AND A DISPLAY DEVICE INCLUDING THE SAME

(71) Applicant: LG ELECTRONICS INC., Seoul (KR)

(72) Inventor: Hooyoung SONG, Seoul (KR)

(73) Assignee: LG ELECTRONICS INC., Seoul (KR)

(21) Appl. No.: 17/902,639

(22) Filed: Sep. 2, 2022

(30) Foreign Application Priority Data
Sep. 2, 2021 (KR) PCT/KR2021/011851

(51) Int. Cl. H01L 33/38; H01L 25/16; H01L 23/00; H01L 33/20

(52) U.S. Cl. CPC H01L 33/382; H01L 25/167; H01L 24/95; H01L 33/20; H01L 2224/95101; H01L 2224/95133; H01L 2224/95136; H01L 33/405

(57) ABSTRACT

Discussed is a semiconductor light emitting device for a display panel, a substrate structure for a display panel, and a display device including the substrate structure. A display device including a semiconductor light emitting device can include a first electrode and a second electrode spaced apart from each other on a predetermined substrate, an insulating layer disposed on the first and second electrodes, a first barrier wall disposed on the insulating layer and including a first assembling hole and a semiconductor light emitting device disposed in the first assembling hole of the first barrier wall. Also, the semiconductor light emitting device can include a light emitting structure, a passivation layer on the light emitting structure, and a first reflective alignment structure disposed in the light emitting structure.

### CROSS-REFERENCE TO RELATED APPLICATION

Pursuant to 35 U.S.C. § 119(a), this application claims the benefit of an earlier filing date of and the right of priority to PCT Application No. PCT/KR2021/011851, filed on Sep. 2, 2021, the contents of which are incorporated by reference herein in its entirety.

### BACKGROUND OF THE DISCLOSURE

### 1. Field of the Disclosure

The embodiment relates to a semiconductor light emitting device for a display panel, a substrate structure for a display panel, and a display device including the same.

### 2. Discussion of the Related Art

Large-area displays include liquid crystal displays (LCD), OLED displays, and micro-LED displays.

A micro-LED display is a display using a micro-LED, which is a semiconductor light emitting device having a diameter or cross-sectional area of 100 μm or less, as a display device.

Micro-LED display uses micro-LED, which is a semiconductor light emitting device, as a display device. The Micro-LED display using the micro-LED has excellent performance in many characteristics such as contrast ratio, response speed, color gamut, viewing angle, brightness, resolution, lifespan, luminous efficiency and luminance.

In particular, micro-LED displays have the advantage of being able to separate and combine screens in a modular way, so that size or resolution can be freely adjusted and flexible displays can be implemented.

However, since large-sized micro-LED displays require millions of micro-LEDs, there is a technical problem in that it is difficult to quickly and accurately transfer micro-LEDs to a display panel.

Transfer technologies that have been recently developed include a pick and place process, a laser lift-off method, or a self-assembly method.

Among these, the self-assembly method is a method in which the semiconductor light emitting device finds an assembly position in a fluid and is advantageous for realization of a large-screen display device.

Recently, although a micro-LED structure suitable for self-assembly has been proposed in U.S. Pat. No. 9,825,202, etc., research on a technology for manufacturing a display through self-assembly of micro-LED is still insufficient.

In particular, in the case of rapidly transferring millions of semiconductor light emitting devices to a large display in the prior art, although the transfer speed can be improved, there is a technical problem in that the transfer error rate can be increased, so that the transfer yield is lowered.

In the related art, a self-assembly method using dielectrophoresis (DEP) has been attempted, but the self-assembly rate is low due to the non-uniformity of the DEP force.

Meanwhile, according to the undisclosed internal technology, self-assembly requires a DEP force, but due to the difficulty of uniform control of the DEP force, there is a problem in that the semiconductor light emitting device is tilted to a different location in the assembly hole during assembly using self-assembly.

On the other hand, in internal technology, in order for the R, G, and B LED chips to be accurately assembled in the respective assembly hole, a study on the shape exclusiveness between the chips by color was conducted by varying the horizontal cross-sectional shapes of the R, G, and B LED chips.

For example, according to an undisclosed internal description, the horizontal cross section of the R LED chip is a circular cross section. Based on this, the major axis is increased by a certain length and the minor axis is decreased to form two oval shapes to manufacture B LED and G LED. In addition, assembly hole patterns (one circle, two ovals) corresponding to these circular and elliptical LEDs were formed on the substrate.

In addition, spaced apart assembly electrodes were formed inside the assembly hole so that the LED could be assembled inside the assembly hole, and each assembly electrode was arranged to be overlapped with the LED chip. Then, an electric field was formed between the two opposite assembly electrodes to assemble the micro LED by dielectrophoretic force.

However, according to an internal study, even if the shapes of R, G, and B LED chips are exclusivity, the applied DEP force is not similar or different, so there is a screen effect problem in that other LED chips block the entrance to the assembly hole. For example, in the assembly hole for the B LED chip, there is a screen effect problem in which the R LED chip or the G LED chip blocks the entrance of the assembly hole, and accordingly, there is a problem of a decrease in DEP selectivity between the LED chips.

On the other hand, when an attempt is made to increase the exclusivity by increasing the difference in the cross-sectional of the R, G, and B LED chips to improve the DEP selectivity by increasing the DEP force deviation in each assembly hole between these R, G, and B LED chips, due to the elliptical LED chip and the shape of the oval assembly hole, a technical contradiction occurs in which the assembling probability of being seated in the assembly hole can be reduced.

On the other hand, according to internal research, when the diameter of a micro LED becomes smaller than 10 μm, it is difficult to produce an elliptical shape, and the luminous efficiency is lowered.

Accordingly, there is a limit to increasing the selectivity of the R, G, and B chips by controlling the shape of the micro LED when it is necessary to produce a micro LED with a diameter of about 10 μm.

Accordingly, there is a need for a method to increase the selectivity of the R, G, and B LED chips while maintaining the same shape of the R, G, and B LED chips.

Meanwhile, in a horizontal LED chip in which electrodes are to be positioned in the same direction among internal technologies, the n-type pad and the p-type pad on the panel must be electrically connected to the n-type electrode and the p-type electrode of the LED chip, respectively.

However, on the panel, the n-type pad and the p-type pad are located opposite to each other, and when the LED chip is rotated 180° and assembled in the opposite direction, a failure can occur in the electrical connection.

However, when assembling LED chips by the force of dielectrophoresis in a fluid, there is a lot of difficulty in assembling the n-type electrode and the p-type electrode of the LED chip to correspond to the n-type pad and the p-type pad on the panel by accurately aligning them at the correct position without rotation or tilting.

Accordingly, the internal technology responds to the alignment issue by exposing the n-type semiconductor layer as a circular mesa and forming the n-type electrode in a circular shape.

However, in order to mesa-etch the n-type semiconductor layer in a circular fashion, as the active layer is also removed by the mesa etching, the light emitting region is removed, and the luminance can be lowered As the internal luminous efficiency is lowered.

Accordingly, there is a demand for technological development capable of accurately aligning the pads of the panel with the electrodes of the LED chip while improving the luminance by minimizing the loss of the active layer.

### SUMMARY OF THE DISCLOSURE

One of the technical problems of the embodiment is to provide a semiconductor light emitting device for a display panel that can increase the assembly selectivity between the R, G, and B LED chips while maintaining the same shape of the LED chip for the display panel and a substrate structure for a display panel and a display device including the same.

Also, in LED chip for display panel, one of the technical problems of the embodiment is to provide a semiconductor light emitting device for a display panel, a substrate structure for a display panel and a display device including the same that can precisely align the pads of the panel with the electrodes of the LED chip while improving the luminance by minimizing the loss of the active

The technical problems of the embodiment are not limited to those described in this item, and include those identified from the description of the invention.

A substrate structure for a display panel according to an embodiment can include a first electrode and a second electrode disposed to be spaced apart from each other on a predetermined substrate, an insulating layer disposed on the first and second electrodes, and a first barrier wall disposed on the insulating layer and including a first assembly hole.

The first electrode can include a first electrode body and a first protruding electrode protruding from the first electrode body toward the second electrode.

The second electrode can include a second electrode body and a second protruding electrode protruding from the second electrode body toward the first electrode.

The first protruding electrode and the second protruding electrode can be disposed to face each other.

In addition, in the semiconductor light emitting device disposed on the substrate structure for a display panel including the first electrode and the second electrode according to the embodiment, the semiconductor light emitting device for a display panel can include a light emitting structure, a passivation layer on the light emitting structure, and a first reflective alignment structure disposed in the light emitting structure.

The first reflective alignment structure can be formed of a metal layer or a high-k metal oxide.

The dielectric constant of the first reflective alignment structure can be greater than that of the light emitting structure.

A display device including a semiconductor light emitting device according to an embodiment can include a first electrode and a second electrode spaced apart from each other on a predetermined substrate, an insulating layer disposed on the first and second electrodes, a first barrier wall disposed on the insulating layer and including a first assembly hole, and a semiconductor light emitting device disposed in the first assembly hole of the first barrier wall.

The semiconductor light emitting device can include a light emitting structure, a passivation layer on the light emitting structure, and a first reflective alignment structure disposed in the light emitting structure.

The first electrode can include a first electrode body and a first protruding electrode protruding from the first electrode body toward the second electrode.

The second electrode can include a second electrode body and a second protruding electrode protruding from the second electrode body toward the first electrode.

The first protruding electrode and the second protruding electrode can be disposed to face each other.

The first reflective alignment structure can be formed of a metal layer or a high-k metal oxide.

The dielectric constant of the first reflective alignment structure can be greater than that of the light emitting structure.

The first reflective alignment structure can be disposed at a position overlapping the first protruding electrode and the second protruding electrode.

The first reflective alignment structure may protrude upwardly of the light emitting structure.

A second axial-directional second-first width of the first reflective alignment structure is greater than a second axial-directional first protrusion width of the first protruding electrode, and can be greater than a second axial second protrusion width of the second protruding electrode.

The light emitting structure includes a first conductivity type semiconductor layer, an active layer and a second conductivity type semiconductor layer. Also, the light emitting structure further comprises a first electrode layer electrically connected to the first conductivity type semiconductor layer and a second electrode layer electrically connected to the second conductivity type semiconductor layer. Also, the first reflective alignment structure may overlap at least a portion of the first electrode layer or the second electrode layer and vertically.

The surface of the first reflective alignment structure can include a roughness.

The first reflective alignment structure can include a first reflective alignment body and a first reflective protrusion protruding from the first reflective alignment body toward the first electrode layer.

The semiconductor light emitting device can include a repulsive structure disposed in the light emitting structure to be spaced apart from the first reflective alignment structure.

The second electrode can include a second-second electrode body and a second-second protrusion electrode protruding from the second-second electrode body toward the first electrode.

Also, the second-second electrode body may not overlap the semiconductor light emitting device upper and lower.

According to the semiconductor light emitting device for a display panel, a substrate structure for a display panel, and a display device including the same, the shape of the LED chip for the display panel has the technical effect of increasing the assembly selectivity between the R, G, and B LED chips while maintaining the same shape.

For example, the first electrode 201 of the first assembly substrate structure 200A of the embodiment can include a first protruding electrode 201p protruding in the direction of the second electrode 202, the second electrode 202 can include a second protruding electrode 202p protruding toward the first electrode 201. The first protruding electrode 201p and the second protruding electrode 202p can be disposed to face each other.

Through this, when AC power is applied to the first electrode 201 and the second electrode 202, the DEP force can be intensively formed between the first protruding electrode 201p and the second protruding electrode 202p.

In addition, the first reflective alignment structure 170a provided in the first semiconductor light emitting device 150A of the embodiment can be disposed at a position overlapping with the first electrode 201 and the second electrode 202 at the same time. Accordingly, the DEP force can be maximized.

In addition, as the DEP force on the first reflective alignment structure 170a is maximized, when the first semiconductor light emitting device 150A is assembled, the upper and lower sides are reversed to prevent misassemble, and the probability of the normal assembly rate can be significantly improved.

In addition, as the DEP force is maximized, the first reflective alignment structure 170a is positioned on the first electrode 201 and the second electrode 202 and assembling proceeds, there is a special technical effect of remarkably improving the alignment accuracy of the first electrode layer 154a and the second electrode layer 154b of the first semiconductor light emitting device 150A and controlling the assembly position and assembly direction of the first semiconductor light emitting device 150A.

For example, in the embodiment, the first reflective alignment structure 170a is disposed to overlap the first electrode layer 154a of the first semiconductor light emitting device 150A, since the dielectric constant of the first reflective alignment structure 170a is greater than that of the light emitting structure 152, the DEP force can be concentrated on the first reflective alignment structure 170a. Accordingly, since the first reflective alignment structure 170a is positioned between the first protruding electrode 201p and the second protruding electrode 202p, there is a special technical effect serving as an alignment key of the first semiconductor light emitting device 150A.

Also, in the embodiment, the surface of the first reflective alignment structure 170a can have roughness (not shown). Accordingly, as the light emitted from the active layer is reflected by the first reflective alignment structure 170a, light extraction efficiency is improved, thereby having a complex effect of improving the luminance of the display.

Also, as the first reflective alignment structure 170a protrudes in the direction of the first electrode layer 154a or the second electrode layer 154b, the volume occupied by the first semiconductor light emitting device 150A is maximized, thereby maximizing the DEP force.

Also, according to the embodiment, in the LED chip for a display panel, there is a technical effect of minimizing the loss of the active layer to improve the luminance and accurately align the pads of the panel with the electrodes of the LED chip.

Also, it is difficult to assemble the third semiconductor light emitting device 150C due to a difference in horizontal cross section from the first assembling hole 203a or the second assembling hole 203b. Also, the position of the third reflective alignment structure 170c is not affected by the DEP force in the positions of the first assembly hole 203a and the second assembly hole 203b. Accordingly, there is a special technical effect that can significantly increase the assembly selectivity between chips by organically combining the shape of the assembly hole, control of the cross-sectional shape of the light emitting device, the position of the protruding electrode, and the arrangement relationship of the first reflective alignment structure.

The technical effects of the embodiments are not limited to those described in this item, and include those identified from the description of the invention.

### BRIEF DESCRIPTION OF THE DRAWINGS

FIG. 1 is an exemplary view of a living room of a house in which a display device according to an embodiment is disposed.

FIG. 2 is a block diagram schematically showing a display device according to an embodiment.

FIG. 3 is a circuit diagram showing an example of the pixel of FIG.

FIG. 4 is an enlarged view of a first panel area in the display device of FIG. 1

FIG. 5 is a cross-sectional view taken along line B1-B2 of area A2 of FIG. 4

FIG. 6 is an exemplary view in which the light emitting device according to the embodiment is assembled on a substrate by a self-assembly method.

FIG. 7 is a partially enlarged view of area A3 of FIG. 6.

FIG. 8A is an assembly substrate structure 200A1 according to an embodiment.

FIG. 8B is an exemplary view of semiconductor light emitting devices disposed on the assembly substrate structure 200A1 according to FIG. 8A.

FIG. 8C is an exemplary view of the assembly hole shown in FIG. 8A.

FIG. 9A is a plan view in which a circular first semiconductor light emitting device is positioned on a third assembling hole having an elliptical shape

FIG. 9B is a cross-sectional view taken along line C1-C2 in FIG. 9A;

FIG. 10A is a plan view in which a first semiconductor light emitting device is inserted into a third assembling hole having an elliptical shape;

FIG. 10B is a cross-sectional view taken along line C1-C2 in FIG. 10A.

FIG. 11A is a plan view of a semiconductor light emitting device display 301 according to a first embodiment.

FIG. 11B is a detailed plan view of the semiconductor light emitting device display 301 according to the first embodiment shown in FIG. 11A.

FIG. 12A is a cross-sectional view taken along line C1-C2 of the semiconductor light emitting device display 301 according to the first embodiment shown in FIG. 11B

FIG. 12B is a cross-sectional view taken along line C3-C4 of the semiconductor light emitting device display 301 according to the first embodiment shown in FIG. 11B

FIGS. 13A and 13B are detailed plan views of the semiconductor light emitting device display 301 according to the first embodiment shown in FIG. 12A

FIG. 14A is a detailed plan view of the first semiconductor light emitting device 150A and the second semiconductor light emitting device 150B in the first semiconductor light emitting device display shown in FIG. 11B.

FIG. 14B is a cross-sectional view taken along the line C1-C2 of the first semiconductor light emitting device 150A and the second semiconductor light emitting device 150B shown in FIG. 14A.

FIG. 14C is a cross-sectional view taken along line C3-C4 of the first semiconductor light emitting device 150A and the second semiconductor light emitting device 150B shown in FIG. 14A.

FIGS. 15A and 15B are assembly views of the semiconductor light emitting device display 301 according to the first embodiment.

FIGS. 16A and 16B are assembly comparative example (R1) when the first semiconductor light emitting device 150A and the second semiconductor light emitting device 150B according to the embodiment are positioned in the second assembly substrate structure 200B and the first assembly substrate structure 200A, respectively

FIG. 17A is a plan view of a second semiconductor light emitting device display 302 according to an embodiment.

FIGS. 17B and 17C are assembly views based on a cross-sectional view taken along line C1-C2 of the second semiconductor light emitting device display 302 shown in FIG. 17A.

FIGS. 18A and 18B are assembly comparative example (R2) when the first-second semiconductor light emitting device 150A2 and the second-second semiconductor light emitting device 150B2 according to the embodiment are positioned in the second assembly substrate structure 200B and the first assembly substrate structure 200A, respectively.

FIG. 19A is a plan view of a third semiconductor light emitting device display 303 according to an embodiment.

FIG. 19B is a cross-sectional view taken along line C1-C2 of the third semiconductor light emitting device display 303 shown in FIG. 19A.

FIGS. 20A and 20B are plan views of a fourth semiconductor light emitting device display 304 according to an embodiment.

### DETAILED DESCRIPTION OF THE DISCLOSURE

Hereinafter, embodiments disclosed in the present description will be described in detail with reference to the accompanying drawings. The suffixes ‘module’ and ‘part’ for components used in the following description are given or mixed in consideration of ease of specification, and do not have a meaning or role distinct from each other by themselves. In addition, the accompanying drawings are provided for easy understanding of the embodiments disclosed in the present specification, and the technical ideas disclosed in the present specification are not limited by the accompanying drawings. Also, when an element, such as a layer, region, or substrate, is referred to as being ‘on’ another component, this includes that it is directly on the other element or there can be other intermediate elements in between.

The display device described in this specification includes a digital TV, a mobile phone, a smart phone, a laptop computer, a digital broadcasting terminal, a personal digital assistant (PDA), a portable multimedia player (PMP), a navigation, a Slate PC, a Tablet PC, an Ultra-Book, a desktop computer, and the like. However, the configuration according to the embodiment described in this specification can be applied to a display capable device even if it is a new product form to be developed later.

Hereinafter, a light emitting device according to an embodiment and a display device including the light emitting device will be described.

Hereinafter, a display device of a semiconductor light emitting device according to an embodiment will be described.

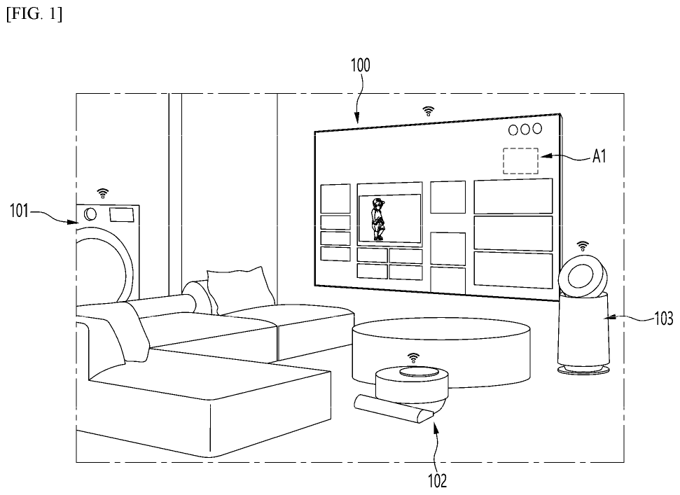

FIG. 1 shows a living room of a house in which a display device 100 according to an embodiment is disposed.

The display device 100 of the embodiment may display the status of various electronic products such as the washing machine 101, the robot cleaner 102, and the air purifier 103, and communicate with each electronic product based on TOT, and may control each electronic product based on the user's setting data.

The display apparatus 100 according to the embodiment can include a flexible display manufactured on a thin and flexible substrate. The flexible display can be bent or rolled like paper while maintaining the characteristics of a conventional flat panel display.

In the flexible display, visual information can be implemented by independently controlling light emission of unit pixels arranged in a matrix form. A unit pixel means a minimum unit for realizing one color. The unit pixel of the flexible display can be implemented by a light emitting device. In an embodiment, the light emitting device can be a Micro-LED or a Nano-LED, but is not limited thereto.

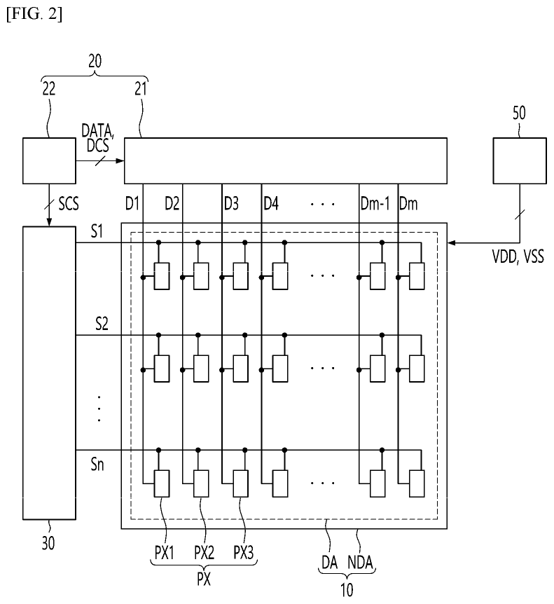

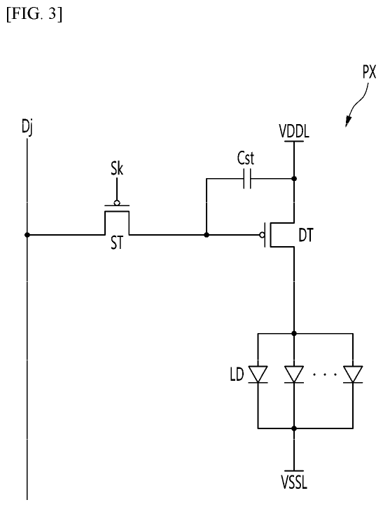

Next, FIG. 2 is a block diagram schematically showing a display device according to an embodiment, and FIG. 3 is a circuit diagram showing an example of the pixel of FIG. 2.

Referring to FIGS. 2 and 3, the display device according to the embodiment can include a display panel 10, a driving circuit 20, a scan driving unit 30, and a power supply circuit 50.

The display device 100 according to the embodiment may drive the light emitting device using an active matrix (AM) method or a passive matrix (PM, passive matrix) method.

The driving circuit 20 can include a data driving unit 21 and a timing control unit 22.

The display panel 10 can be divided into a display area DA and a non-display area NDA disposed around the display area DA. The display area DA is an area in which pixels PX are formed to display an image. The display panel 10 includes data lines (D1 to Dm, m is an integer greater than or equal to 2), scan lines crossing the data lines D1 to Dm (S1 to Sn, n is an integer greater than or equal to 2), the high-potential voltage line supplied with the high-voltage, the low-potential voltage line supplied with the low-potential voltage, and the pixels PX connected to the data lines D1 to Dm and the scan lines S1 to Sn can be included.

Each of the pixels PX can include a first sub-pixel PX1, a second sub-pixel PX2, and a third sub-pixel PX3. The first sub-pixel PX1 emits a first color light of a first wavelength, the second sub-pixel PX2 emits a second color light of a second wavelength, and the third sub-pixel PX3 emits a third color light of a wavelength can be emitted. The first color light can be red light, the second color light can be green light, and the third color light can be blue light, but is not limited thereto. Also, although it is illustrated that each of the pixels PX includes three sub-pixels in FIG. 2, the present invention is not limited thereto. That is, each of the pixels PX can include four or more sub-pixels.

Each of the first sub-pixel PX1, the second sub-pixel PX2, and the third sub-pixel PX3 may connected to at least one of the data lines D1 to Dm, and at least one of the scan lines 51 to Sn, and a high potential voltage line. As shown in FIG. 3, the first sub-pixel PX1 can include the light emitting devices LD, plurality of transistors for supplying current to the light emitting devices LD, and at least one capacitor Cst.

Although not shown in the drawing, each of the first sub-pixel PX1, the second sub-pixel PX2, and the third sub-pixel PX3 can include only one light emitting device LD and at least one capacitor Cst.

Each of the light emitting devices LD can be a semiconductor light emitting diode including a first electrode, a plurality of conductivity type semiconductor layers, and a second electrode. Here, the first electrode can be an anode electrode and the second electrode can be a cathode electrode, but the present invention is not limited thereto.

Referring to FIG. 3, the plurality of transistors can include a driving transistor DT for supplying current to the light emitting devices LD, and a scan transistor ST for supplying a data voltage to the gate electrode of the driving transistor DT. The driving transistor DT can include a gate electrode connected to the source electrode of the scan transistor ST, a source electrode connected to a high potential voltage line to which a high potential voltage is applied, and a drain electrode connected to first electrodes of the light emitting devices LD. The scan transistor ST can include a gate electrode connected to the scan line Sk, where k is an integer satisfying l≤k≤n, a source electrode connected to the gate electrode of the driving transistor DT, and a drain electrode connected to data lines Dj, where j is integer satisfying l≤j≤m.

The capacitor Cst is formed between the gate electrode and the source electrode of the driving transistor DT. The storage capacitor Cst may charge a difference between the gate voltage and the source voltage of the driving transistor DT.

The driving transistor DT and the scan transistor ST can be formed of a thin film transistor. In addition, although the driving transistor DT and the scan transistor ST have been mainly described in FIG. 3 as being formed of a P-type MOSFET (Metal Oxide Semiconductor Field Effect Transistor), the present invention is not limited thereto. The driving transistor DT and the scan transistor ST can be formed of an N-type MOSFET. In this case, the positions of the source electrode and the drain electrode of each of the driving transistor DT and the scan transistor ST can be changed.

Also, in FIG. 3 has been illustrated each of the first sub-pixel PX1, the second sub-pixel PX2, and the third sub-pixel PX3 includes one driving transistor DT, one scan transistor ST, and 2T1C (2 Transistor—1 capacitor) having a capacitor Cst, but the present invention is not limited thereto. Each of the first sub-pixel PX1, the second sub-pixel PX2, and the third sub-pixel PX3 can include a plurality of scan transistors ST and a plurality of capacitors Cst.

Referring back to FIG. 2, the driving circuit 20 outputs signals and voltages for driving the display panel 10. To this end, the driving circuit 20 can include a data driver 21 and a timing controller 22.

The data driver 21 receives digital video data DATA and a source control signal DCS from the timing controller 22. The data driver 21 converts the digital video data DATA into analog data voltages according to the source control signal DCS and supplies them to the data lines D1 to Dm of the display panel 10.

The timing controller 22 receives digital video data DATA and timing signals from the host system. The timing signals can include a vertical sync signal, a horizontal sync signal, a data enable signal, and a dot clock. The host system can be an application processor of a smartphone or tablet PC, a monitor, or a system-on-chip of a TV.

The scan driver 30 receives the scan control signal SCS from the timing controller 22. The scan driver 30 generates scan signals according to the scan control signal SCS and supplies them to the scan lines S1 to Sn of the display panel 10. The scan driver 30 can include a plurality of transistors and can be formed in the non-display area NDA of the display panel 10. Also, the scan driver 30 can be formed of an integrated circuit, and in this case, can be mounted on a gate flexible film attached to the other side of the display panel 10.

The power supply circuit 50 generates a high potential voltage VDD and a low potential voltage VSS for driving the light emitting devices LD of the display panel 10 from the main power source, and the power supply circuit may supply VDD and VSS to the high-potential voltage line and the low-potential voltage line of the display panel 10. Also, the power supply circuit 50 may generate and supply driving voltages for driving the driving circuit 20 and the scan driving unit 30 from the main power.

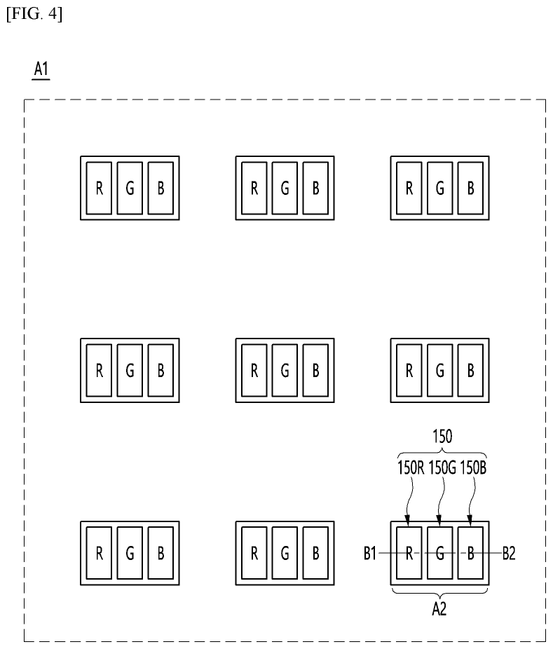

Next, FIG. 4 is an enlarged view of the first panel area A1 in the display device of FIG.

Referring to FIG. 4, the display device 100 according to the embodiment can be manufactured by mechanically and electrically connecting a plurality of panel areas such as the first panel area A1 by tiling.

The first panel area A1 can include a plurality of light emitting devices 150 arranged for each unit pixel (PX in FIG. 2).

For example, the unit pixel PX can include a first sub-pixel PX1, a second sub-pixel PX2, and a third sub-pixel PX3. For example, a plurality of red light-emitting devices 150R are disposed in the first sub-pixel PX1, a plurality of green light-emitting devices 150G are disposed in the second sub-pixel PX2, and a plurality of blue light-emitting devices 150B are disposed in the third sub-pixel PX3. The unit pixel PX may further include a fourth sub-pixel in which a light emitting device is not disposed, but is not limited thereto. Meanwhile, the light emitting device 150 can be the semiconductor light emitting device.

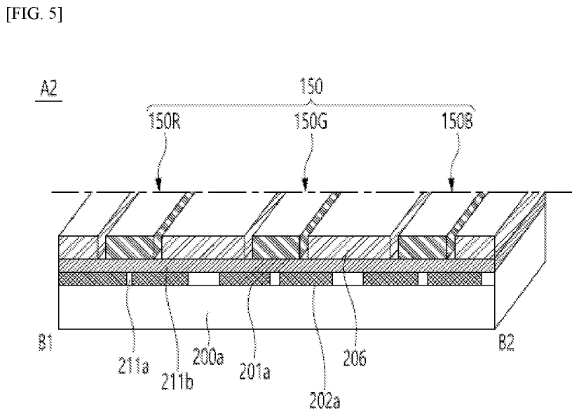

Next, FIG. 5 is a cross-sectional view taken along line B1-B2 of area A2 of FIG. 4.

Referring to FIG. 5, the display device 100 of the embodiment includes a substrate 200a, wirings 201a and 202a spaced apart from each other, a first insulating layer 211a, a second insulating layer 211b, a third insulating layer 206 and a plurality of light emitting devices 150.

The wiring can include a first wiring 201a and a second wiring 202a spaced apart from each other. The first wiring 201a and the second wiring 202a may function as panel wiring for applying power to the light emitting device 150 in the panel, and in the case of self-assembly of the light emitting device 150, also, the first wiring 201a and the second wiring 202a may function as an assembled electrode for generating a dielectrophoresis force.

The wirings 201a and 202a can be formed of a transparent electrode (ITO) or include a metal material having excellent electrical conductivity. For example, the wirings 201a and 202a can be formed at least one of titanium (Ti), chromium (Cr), nickel (Ni), aluminum (Al), platinum (Pt), gold (Au), tungsten (W), molybdenum (Mo) or an alloy thereof.

A first insulating layer 211a can be disposed between the first wiring 201a and the second wiring 202a, and a second insulating layer 211b can be disposed on the first wiring 201a and the second wiring 202a. The first insulating layer 211a and the second insulating layer 211b can be an oxide film, a nitride film, or the like, but are not limited thereto.

The light emitting device 150 can include a red light emitting device 150R, a green light emitting device 150G, and a blue light emitting device 150B0 to form a sub-pixel, respectively, but is not limited thereto. The light emitting device 150 can include a red phosphor and a green phosphor to implement red and green, respectively

The substrate 200a can be formed of glass or polyimide. Also, the substrate 200a can include a flexible material such as polyethylene naphthalate (PEN) or polyethylene terephthalate (PET). In addition, the substrate 200 can include a transparent material, but is not limited thereto. The substrate 200a may function as a support substrate in the panel, and may function as a substrate for assembly when self-assembling the light emitting device.

The third insulating layer 206 can include an insulating and flexible material such as polyimide, PEN, or PET, and can be integrally formed with the substrate 200a to form one substrate.

The third insulating layer 206 can be a conductive adhesive layer having adhesiveness and conductivity, and the conductive adhesive layer can be flexible to enable a flexible function of the display device. For example, the third insulating layer 206 can be an anisotropy conductive film (ACF) or a conductive adhesive layer such as an anisotropic conductive medium or a solution containing conductive particles. The conductive adhesive layer can be a layer that is electrically conductive in a direction perpendicular to the thickness but electrically insulating in a direction horizontal to the thickness.

The distance between the first and second wirings 201a and 202a is formed to be smaller than the width of the light emitting device 150 and the width of the assembly hole 203H, so that the assembly position of the light emitting device 150 using an electric field can be more precisely fixed.

A third insulating layer 206 is formed on the first and second wirings 201a and 202a to protect the first and second wirings 201a and 202a from the fluid 1200, and the third insulating layer 206 is can prevent leakage of current flowing through the two wirings 201a and 202a. The third insulating layer 206 can be formed of a single layer or multiple layers of an inorganic insulator such as silica or alumina or an organic insulator.

In addition, the third insulating layer 206 can include an insulating and flexible material such as polyimide, PEN, PET, etc., and can be formed integrally with the substrate 200 to form a single substrate.

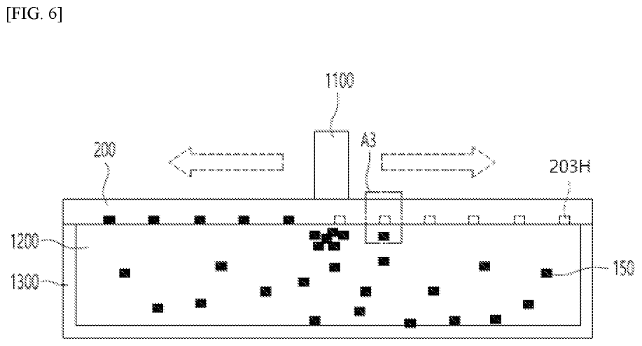

The third insulating layer 206 has a barrier wall, and an assembly hole 203H can be formed by the barrier wall. For example, the third insulating layer 206 can include an assembly hole 203H through which the light emitting device 150 is inserted (refer to FIG. 6). Accordingly, during self-assembly, the light emitting device 150 can be easily inserted into the assembly hole 203H of the third insulating layer 206. The assembly hole 203H can be referred to as an insertion hole, a fixing hole, or an alignment hole.

The assembly hole 203H can have a shape and a size corresponding to the shape of the light emitting device 150 to be assembled at a corresponding position. Accordingly, it is possible to prevent other light emitting devices from being assembled in the assembly hole 203H or from assembling a plurality of light emitting devices.

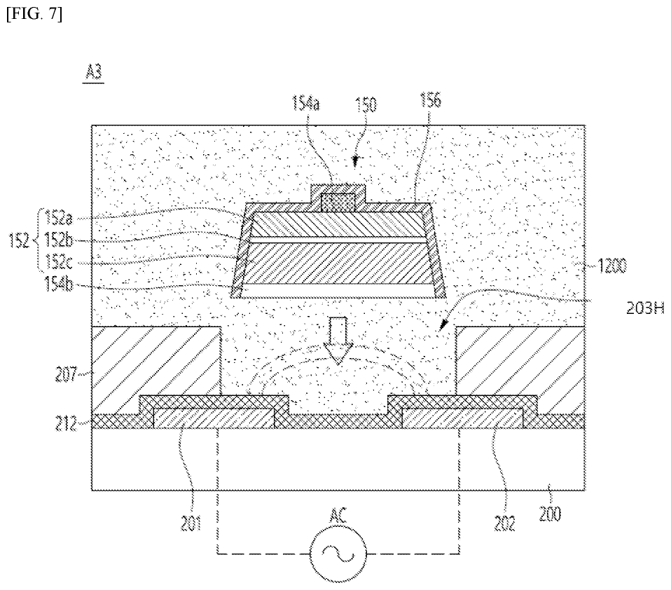

Next, FIG. 6 is a view showing an example in which the light emitting device according to the embodiment is assembled on a substrate by a self-assembly method, and FIG. 7 is a partially enlarged view of area A3 of FIG. 6. And FIG. 7 is a diagram illustrating a state in which area A3 is rotated 180 degrees for convenience of explanation.

An example in which the semiconductor light emitting device according to the embodiment is assembled in a display panel by a self-assembly method using an electromagnetic field will be described with reference to FIGS. 6 and 7.

The assembly substrate 200 to be described later may also function As the panel substrate 200a in the display device after assembly of the light emitting device, but the embodiment is not limited thereto.

Referring to FIG. 6, the semiconductor light emitting device 150 can be put into the chamber 1300 filled with the fluid 1200, and the semiconductor light emitting device 150 by the magnetic field generated from the assembly device 1100 may move to the assembly substrate 200. In this case, the light emitting device 150 adjacent to the assembly hole 203H of the assembly substrate 200 can be assembled in the assembly hole 230 by a dielectrophoretic force by an electric field of the assembly electrodes. The fluid 1200 can be water such as ultrapure water, but is not limited thereto. A chamber can be referred to as a water bath, container, vessel, or the like.

After the semiconductor light emitting device 150 is put into the chamber 1300, the assembly substrate 200 can be disposed on the chamber 1300. According to an embodiment, the assembly substrate 200 can be introduced into the chamber 1300.

Referring to FIG. 7, the semiconductor light emitting device 150 can be implemented as a vertical semiconductor light emitting device as shown, but is not limited thereto, and a horizontal light emitting device can be employed.

The semiconductor light emitting device 150 can include a magnetic layer (not shown) having a magnetic material. The magnetic layer can include a magnetic metal such as nickel (Ni). Since the semiconductor light emitting device 150 injected into the fluid includes a magnetic layer, it can move to the assembly substrate 200 by the magnetic field generated from the assembly device 1100. The magnetic layer can be disposed above or below or on both sides of the light emitting device.

The semiconductor light emitting device 150 can include a passivation layer 156 surrounding the top and side surfaces. The passivation layer 156 can be formed by using an inorganic insulator such as silica or alumina through PECVD, LPCVD, sputtering deposition, or the like. In addition, the passivation layer 156 can be formed through a method of spin coating an organic material such as a photoresist or a polymer material.

The semiconductor light emitting device 150 can include a first conductivity type semiconductor layer 152a, a second conductivity type semiconductor layer 152c, and an active layer 152b disposed between the first conductivity type semiconductor layer 152a and the second conductivity type semiconductor layer 152c. The first conductivity type semiconductor layer 152a can be an n-type semiconductor layer, and the second conductivity type semiconductor layer 152c can be a p-type semiconductor layer, but is not limited thereto.

A first electrode layer 154a can be disposed on the first conductivity type semiconductor layer 152a, and a second electrode layer 154b can be disposed on the second conductivity type semiconductor layer 152c. To this end, a partial region of the first conductivity type semiconductor layer 152a or the second conductivity type semiconductor layer 152c can be exposed to the outside. Accordingly, after the semiconductor light emitting device 150 is assembled on the assembly substrate 200, a portion of the passivation layer 156 can be etched in the manufacturing process of the display device.

The assembly substrate 200 can include a pair of first assembly electrodes 201 and second assembly electrodes 202 corresponding to each of the semiconductor light emitting devices 150 to be assembled. The first assembly electrode 201 and the second assembly electrode 202 can be formed by stacking a single metal, a metal alloy, or a metal oxide in multiple layers. For example, the first assembled electrode 201 and the second assembled electrode 202 can be formed including at least one of Cu, ag, Ni, Cr, ti, Al, Rh, Pd, Ir, Ru, Mg, Zn, Pt, au, or Hf, but is not limited thereto.

In addition, the first assembly electrode 201 and the second assembly electrode 202 can be formed including at least one of indium tin oxide (ITO), indium zinc oxide (IZO), indium zinc tin oxide (IZTO), indium aluminum zinc oxide (IAZO), IGZO (indium gallium zinc oxide), IGTO (indium gallium tin oxide), aZO (aluminum zinc oxide), aTO (antimony tin oxide), GZO (gallium zinc oxide), IZON (IZO Nitride), aGZO (Al—Ga ZnO), IGZO (In—Ga ZnO), ZnO, IrOx, RuOx, NiO, RuOx/ITO, Ni/IrOx/Au, or Ni/IrOx/Au/ITO, and is not limited thereto.

The first assembled electrode 201, the second assembled electrode 202 emits an electric field as an AC voltage is applied, the semiconductor light emitting device 150 inserted into the assembly hole 203H can be fixed by dielectrophoretic force. A distance between the first assembly electrode 201 and the second assembly electrode 202 can be smaller than a width of the semiconductor light emitting device 150 and a width of the assembly hole 203H, the assembly position of the semiconductor light emitting device 150 using the electric field can be more precisely fixed.

An insulating layer 212 is formed on the first assembly electrode 201 and the second assembly electrode 202 to protect the first assembly electrode 201 and the second assembly electrode 202 from the fluid 1200 and leakage of current flowing through the first assembled electrode 201 and the second assembled electrode 202 can be prevented. For example, the insulating layer 212 can be formed of a single layer or multiple layers of an inorganic insulator such as silica or alumina or an organic insulator. The insulating layer 212 can have a minimum thickness to prevent damage to the first assembly electrode 201 and the second assembly electrode 202 when the semiconductor light emitting device 150 is assembled, and it can have a maximum thickness for the semiconductor light emitting device 150 being stably assembled.

A barrier wall 207 can be formed on the insulating layer 212. A portion of the barrier wall 207 can be positioned on the first assembly electrode 201 and the second assembly electrode 202, and the remaining region can be positioned on the assembly substrate 200.

On the other hand, when the assembly substrate 200 is manufactured, a portion of the barrier walls formed on the entire upper portion of the insulating layer 212 is removed, an assembly hole 203H in which each of the semiconductor light emitting devices 150 is coupled and assembled to the assembly substrate 200 can be formed.

An assembly hole 203H to which the semiconductor light emitting devices 150 are coupled is formed in the assembly substrate 200, and a surface on which the assembly hole 203H is formed can be in contact with the fluid 1200. The assembly hole 203H may guide an accurate assembly position of the semiconductor light emitting device 150.

Meanwhile, the assembly hole 203H can have a shape and a size corresponding to the shape of the semiconductor light emitting device 150 to be assembled at a corresponding position. Accordingly, it is possible to prevent assembling other semiconductor light emitting devices or assembling a plurality of semiconductor light emitting devices in the assembly hole 203H.

Referring back to FIG. 6, after the assembly substrate 200 is disposed in the chamber, the assembly device 1100 for applying a magnetic field may move along the assembly substrate 200. The assembly device 1100 can be a permanent magnet or an electromagnet.

The assembly device 1100 may move while in contact with the assembly substrate 200 in order to maximize the area applied by the magnetic field into the fluid 1200. According to an embodiment, the assembly device 1100 can include a plurality of magnetic materials or a magnetic material having a size corresponding to that of the assembly substrate 200. In this case, the moving distance of the assembly device 1100 can be limited within a predetermined range.

The semiconductor light emitting device 150 in the chamber 1300 may move toward the assembly device 1100 and the assembly substrate 200 by the magnetic field generated by the assembly device 1100.

Referring to FIG. 7, the semiconductor light emitting device 150 is moving toward the assembly device 1100, it may enter and be fixed into the assembly hole 203H by a dielectrophoretic force (DEP force) formed by the electric field of the assembly electrode of the assembly substrate.

Specifically, the first and second assembly wirings 201 and 202 may form an electric field by an AC power source, and a dielectrophoretic force can be formed between the assembly wirings 201 and 202 by this electric field. The semiconductor light emitting device 150 can be fixed to the assembly hole 203H on the assembly substrate 200 by this dielectrophoretic force.

At this time, a predetermined solder layer (not shown) is formed between the light emitting device 150 and the assembly electrode assembled on the assembly hole 203H of the assembly substrate 200 to can improve the bonding force of the light emitting device 150.

In addition, a molding layer (not shown) can be formed in the assembly hole 203H of the assembly substrate 200 after assembly. The molding layer can be a transparent resin or a resin including a reflective material and a scattering material.

By the self-assembly method using the electromagnetic field described above, the time required for each of the semiconductor light emitting devices to be assembled on the substrate can be rapidly reduced, so that a large-area high-pixel display can be implemented more quickly and economically.

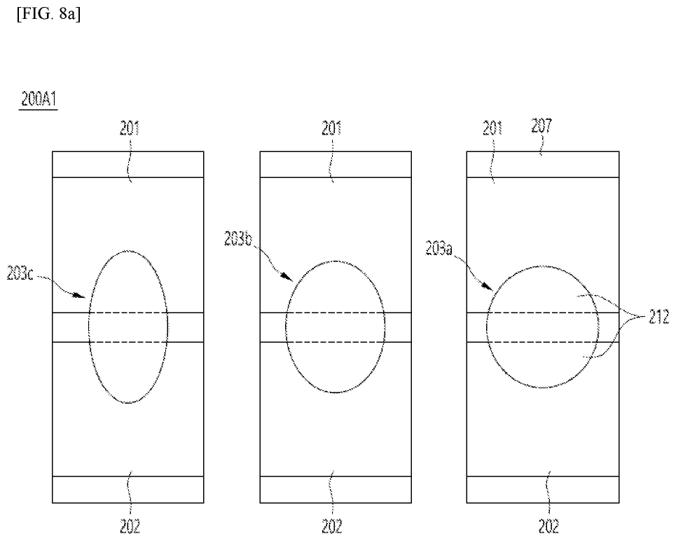

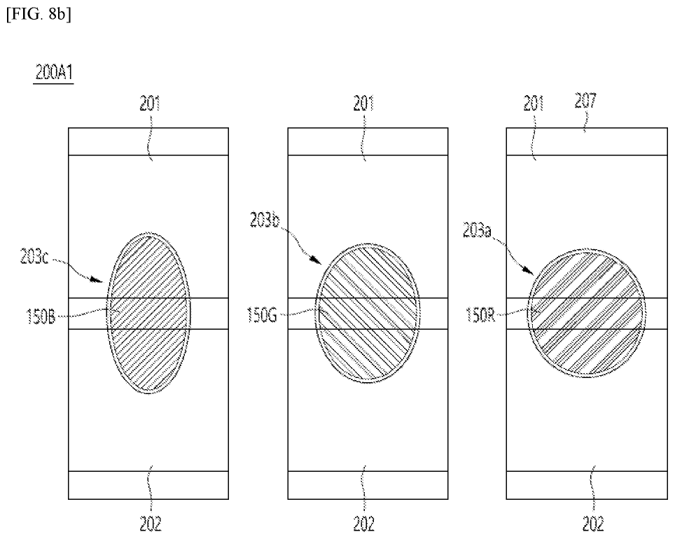

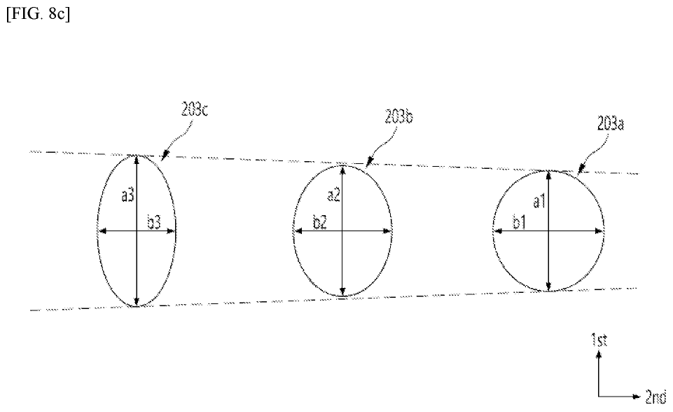

Next, FIG. 8A is an assembly substrate structure 200A1 according to an embodiment, and FIG. 8B is an exemplary view of semiconductor light emitting devices disposed on the assembly substrate structure 200A1 according to FIG. 8A. Also, FIG. 8C is an exemplary view of the assembly hole shown in FIG. 8A.

In the embodiment, the assembly hole of the substrate can have a shape and a size corresponding to the shape of the semiconductor light emitting device to be assembled at the corresponding position. Accordingly, it is possible to prevent assembling other semiconductor light emitting devices or assembling a plurality of semiconductor light emitting devices in the assembly hole.

Also, according to unpublished internal technology, the simultaneous assembly of R micro LED chip, G micro LED chip, and B LED chip using dielectrophoresis is being studied.

However, in order to accurately assemble the R, G, and B LED chips in the respective assembly hole, research on the exclusiveness of the chip shape in which the horizontal cross-sectional shapes of the R, G, and B LED chips are different is being conducted.

For example, referring to FIG. 8A, the assembly substrate structure 200A1 according to the embodiment can include a plurality of first assembly electrodes 201 and second assembly electrodes 202 spaced apart from each other.

Also, the embodiment can include a barrier wall 207 disposed on each of the assembly electrodes 201 and 202.

The barrier wall 207 can include a first assembling hole 203a, a second assembling hole 203b, and a third assembling hole 203c, which are partially removed in consideration of the shape of the light emitting device to be assembled. The insulating layer 212 can be exposed by the first assembly hole 203a, the second assembly hole 203b, and the third assembly hole 203c.

A horizontal cross section of the first assembling hole 203a can be circular, and a horizontal cross section of the second assembling hole 203b and the third assembling hole 203c can be elliptical.

Referring to FIG. 8b, a first semiconductor light emitting device 150R, a second semiconductor light emitting device 150G, and a third semiconductor light emitting device 150B can be assembled in the first assembly hole 203a, the second assembly hole 203b, and the third assembly hole 203c, respectively. The first semiconductor light emitting device 150R can be an R LED chip, the second semiconductor light emitting device 150G can be a G LED chip, and the third semiconductor light emitting device 150B can be a B LED chip.

Next, referring to FIG. 8c, the first assembly hole 203a can have a first width al in the first direction based on the first axis 1st and a first width b1 in the second direction based on a second axis 2nd perpendicular to the first axis, and the first width a1 in the first direction and the first width b1 in the second direction can be the same, but are not limited thereto.

Next, the second assembly hole 203b can have a second width a2 in the first direction and a second width b2 in the second direction, the third assembly hole 203c can have a third width a3 in the first direction and a third width b3 in the second direction.

For example, the first assembly hole 203a can include a circular cross-section in which the first width a1 in the first direction and the first width b1 in the second direction are 38 μm, respectively.

In this case, the second assembling hole 203b and the third assembling hole 203c can have a predetermined exclusion distance based on the first assembling hole 203a. For example, the width in the first direction which is a major axis of the second assembling hole 203b and the third assembling hole 203c is increased at an exclusive interval based on the first assembling hole 203a in the first direction, and the width in the second direction, which is a minor axis, can be reduced. The exclusion interval can be about 5 μm to 10 μm, but is not limited thereto.

For example, if the first assembly hole 203a has a circular cross-section in which the first width a1 in the first direction and the first width b1 in the second direction are 38 μm, respectively, and the exclusion interval is 7 μm, a second width a2 of the second assembly hole 203b in the first direction can be 45 μm, and a width b2 of the second assembly hole 203b in the second direction can be 31 μm.

In addition, the third width a3 in the first direction of the third assembly hole 203c can be 52 μm, and the third width b3 in the second direction can be 24 μm, but is not limited thereto.

On the other hand, so that the LED can be assembled inside the assembly hole, an assembly electrode spaced apart from the inside of the assembly hole is formed, Micro LED is assembled by dielectrophoresis by placing each assembly electrode so that it can overlap on the LED chip and forming an electric field between two opposite assembly electrodes.

However, according to an internal study, even if the shapes of R, G, and B LED chips are exclusivity, the applied DEP force is not similar or different, so there is a screen effect problem in that other LED chips block the entrance to the assembly hole. For example, in the assembly hole for the B LED chip, there is a screen effect problem in which the R LED chip or the G LED chip blocks the entrance of the assembly hole, and accordingly, there is a problem of a decrease in DEP selectivity that prevents the LED chip from being properly assembled.

On the other hand, the DEP force applied to the LED is greatest when it is closest to the assembled electrode, and is proportional to the area overlapped with the assembled electrode.

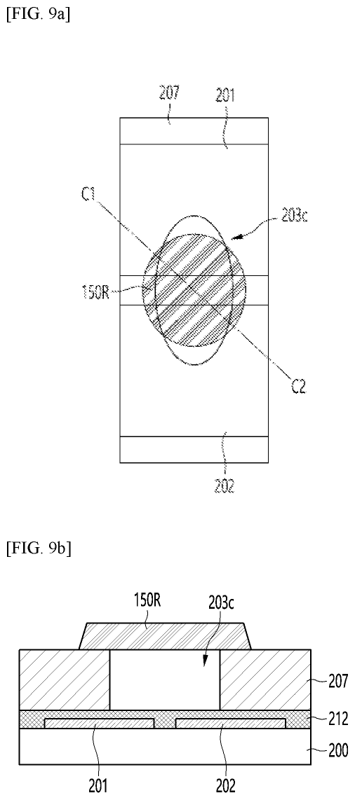

FIG. 9A is a plan view in which the circular first semiconductor light emitting device 150R is positioned on the third assembly hole 203c having an elliptical shape, and FIG. 9B is a cross-sectional view taken along the line C1-C2 in FIG. 9A.

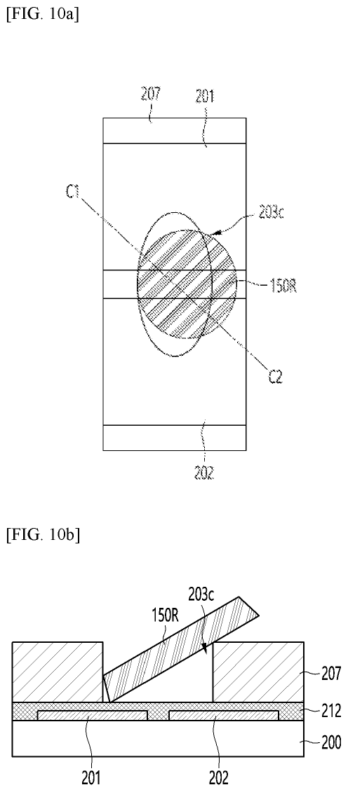

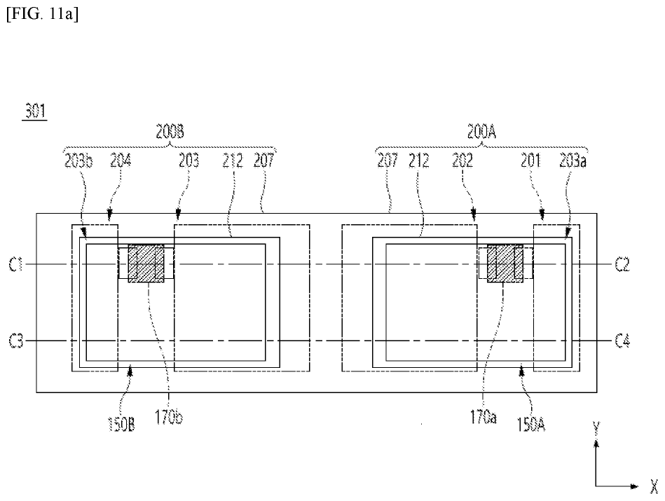

In addition, FIG. 10A is a plan view in which the first semiconductor light emitting device 150R is inserted into the third assembly hole 203c having an elliptical shape, and FIG. 10B is a cross-sectional view taken along line C1-C2 in FIG. 10A.

When even if the shape of the R, G, and B LED chips is exclusive, the applied DEP force is similar or there is no big difference or rotation of the elliptical second semiconductor light emitting device 150G or the third semiconductor light emitting device 150B occurs, the DEP force applied to them can be smaller than the DEP force applied to the circular first semiconductor light emitting device 150R.

Accordingly, as shown in FIGS. 9A and 9B, the circular first semiconductor light emitting device 150R blocks the entrance to the assembly hole in the elliptical third assembly hole 203c or As shown in FIGS. 10A and 10B, a screen or block effect occurs in which the circular first semiconductor light emitting device 150R is partially fitted into the elliptical third assembly hole 203c, there is a problem of a decrease in the selectivity of the DEP that prevents the semiconductor light emitting device corresponding to the pixel from being assembled.

However, in order to increase the deviation of the DEP force in the corresponding assembly hole of these R, G, and B LED chips, the horizontal cross-sectional shape of the R, G, and B LED chips is further increased to increase exclusivity, there is a technical contradiction in which the assembling probability of being seated in the elliptical assembly hole is reduced due to the oval shape of the LED chip.

One of the technical problems of the embodiment is to provide a semiconductor light emitting device for a display panel and substrate structure for display panel and display device including same that can increase the assembly selectivity between R, G, and B LED chips while maintaining the same shape of the LED chip for display panel.

In addition, one of the technical tasks of the embodiment is to provide a semiconductor light emitting device for a display panel and substrate structure for display panel and display device including same that can accurately align the pads of the panel with the electrodes of the LED chip while improving the luminance by minimizing the loss of the active layer in the LED chip for the display panel.

Hereinafter, specific features of the embodiments for solving the technical problems of the present invention will be described in detail with reference to the drawings.

FIG. 11A is a plan view of the semiconductor light emitting device display 301 according to the first embodiment, and FIG. 11B is a detailed plan view of the semiconductor light emitting device display 301 according to the first embodiment shown in FIG. 11A.

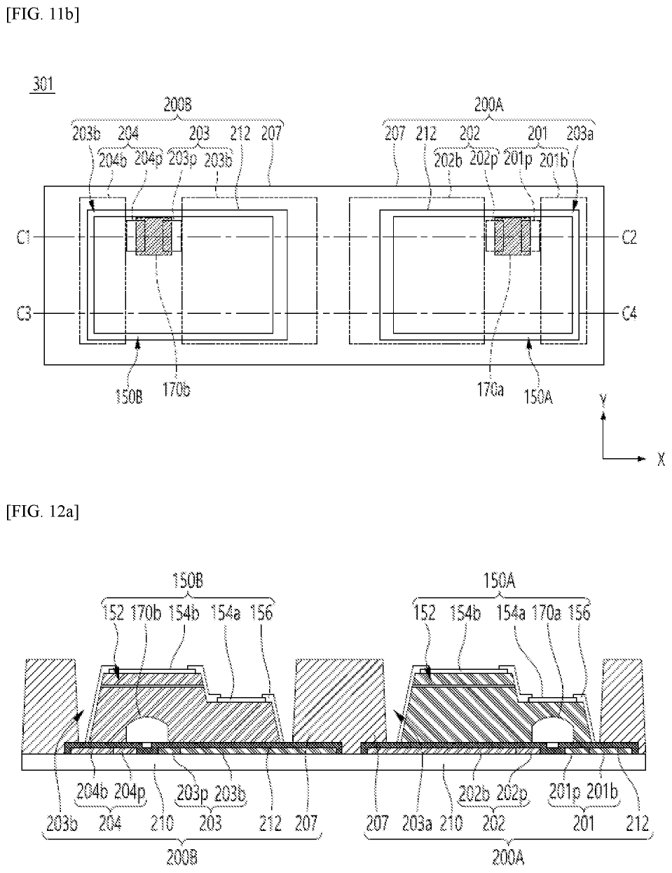

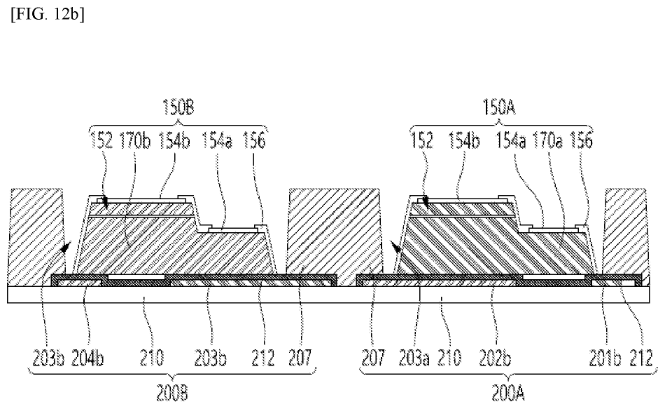

FIGS. 12A and 12B are cross-sectional views of the semiconductor light emitting device display 301 according to the first embodiment shown in FIG. 11B.

Specifically, FIG. 12A is a cross-sectional view taken along line C1-C2 of the semiconductor light emitting device display 301 according to the first embodiment shown in FIG. 11B.

FIG. 12B is a cross-sectional view taken along line C3-C4 of the semiconductor light emitting device display 301 according to the first embodiment shown in FIG. 11B.

Referring to FIG. 11A first, the semiconductor light emitting device display 301 according to the first embodiment can include a first assembly substrate structure 200A and a second assembly substrate structure 200B disposed adjacently.

In addition, the semiconductor light emitting device display 301 according to the first embodiment can include a first semiconductor light emitting device 150A disposed on the first assembly substrate structure 200A and a second semiconductor light emitting device 150B disposed on the second assembly substrate structure 200B.

The first assembly substrate structure 200A can include a first electrode 201 and a second electrode 202 spaced apart from each other on a predetermined substrate 210 (see FIG. 12A), an insulating layer 212 disposed on the first and second electrodes 201 and 202 and a first partition wall 207 disposed on the insulating layer 212 and including a first assembly hole

The first assembly substrate structure 200A can include a first electrode 201 and a second electrode 202 that are spaced apart from each other on a predetermined substrate 210 (see FIG. 12A), an insulating layer 212 disposed on the first and second electrodes 201 and 202 and a first barrier wall 207 disposed on the insulating layer 212 and including a first assembly hole 203a.

Also, the second assembly substrate structure 200B can include a third electrode 203 and a fourth electrode 204 spaced apart from each other on a predetermined substrate 210. An insulating layer 212 can be disposed on the third electrode 203 and the fourth electrode 204. A first barrier wall 207 including a predetermined second assembly hole 203b can be disposed on the insulating layer 212.

As the second semiconductor light emitting device 150B is positioned in the first assembly hole 203b of the second assembly substrate structure 200B and AC power is applied to the third electrode 203 and the fourth electrode 204, the second semiconductor light emitting device 150B can be assembled by DEP force.

Referring to FIG. 11B and cross-sectional views of FIGS. 12A and 12B, in the first assembly substrate structure 200A, the first electrode 201a can include a first electrode body 201b and a first protruding electrode 201p protruding from the first electrode body 201b toward the second electrode 202.

In addition, in the first assembly substrate structure 200A, the second electrode 202 can include a second electrode body 202b and a second protruding electrode 202p protruding from the second electrode body 202b toward the first electrode 201.

The first protruding electrode 201p and the second protruding electrode 202p can be disposed to face each other.

Through this, when AC power is applied to the first electrode 201 and the second electrode 202, a DEP force can be intensively formed between the first protruding electrode 201p and the second protruding electrode 202p.

In this case, the first reflective alignment structure 170a provided in the first semiconductor light emitting device 150A can be disposed at a position overlapping the first electrode 201 and the second electrode 202 at the same time, and thus the DEP force can be maximized.

In addition, as the DEP force applied to the first reflective alignment structure 170a is maximized, the upper and lower sides of the first semiconductor light emitting device 150A are reversed when assembling to prevent a mis-assembly and significantly improve the probability of the normal assembly rate.

In addition, as the DEP force is maximized, the first reflective alignment structure 170a is positioned on the first electrode 201 and the second electrode 202 to be assembled, the alignment accuracy of the first electrode layer 154a and the second electrode layer 154b of the first semiconductor light emitting device 150A can be significantly improved, and there is a special technical effect of controlling the assembly position and the assembly direction of the first semiconductor light emitting device 150A.

Continuing to refer to FIGS. 11B, 12A and 12B, in the second assembly substrate structure 200B, the third electrode 203 can include a third electrode body 203b and a third protruding electrode 203p protruding from the third electrode body 203b toward the fourth electrode 204.

In addition, in the second assembly substrate structure 200B, the fourth electrode 204 can include a fourth electrode body 204b and a fourth protruding electrode 204p protruding from the fourth electrode body 204b toward the third electrode 203. The third protruding electrode 203p and the fourth protruding electrode 204p can be disposed to face each other.

Through this, when AC power is applied to the third electrode 203 and the fourth electrode 204, the DEP force can be formed intensively between the third protruding electrode 203p and the fourth protruding electrode 204p.

Continuing to refer to FIGS. 11B, 12A, and 12B, the first semiconductor light emitting device 150A can be disposed in the first assembly hole 203a of the first assembly substrate structure 200A.

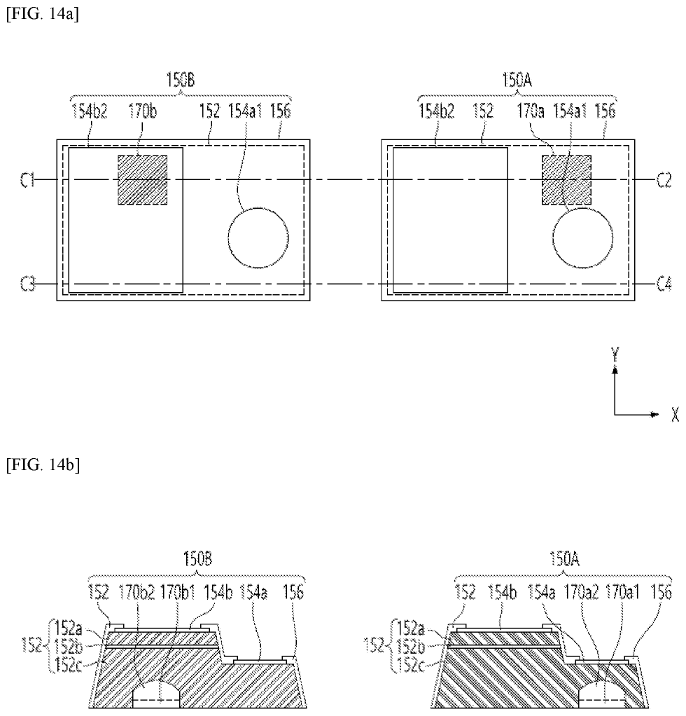

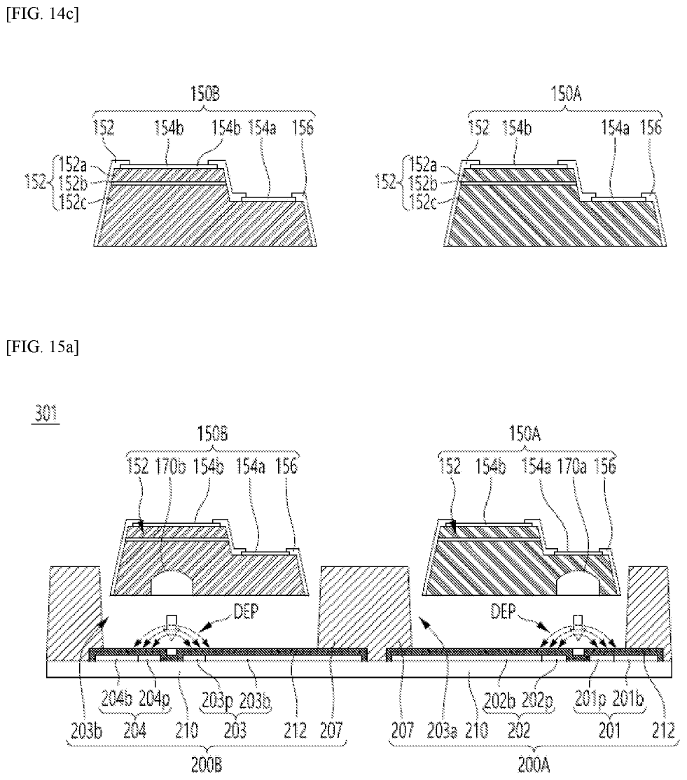

The first semiconductor light emitting device 150A can include a light emitting structure 152 (refer to FIG. 14B), a passivation layer 156 on the light emitting structure 152 and a first reflective alignment structure 170a disposed in the light-emitting structure 152.

The first reflective alignment structure 170a can be disposed at a position overlapping the first protruding electrode 201p and the second protruding electrode 202p.

The first reflective alignment structure 170a can be formed of a metal layer or a high-k metal oxide. For example, the dielectric constant of the first reflective alignment structure 170a can be greater than that of the light emitting structure 152 of the semiconductor light emitting device.

For example, the first reflective alignment structure 170a can be a metal layer including at least one of Ti, Al, Rh, Cu, ag, Ni, Cr, Pd, Ir, Ru, Mg, Zn, Pt, au, or Hf, or can be formed of an oxide or alloy thereof, but is not limited thereto. For example, the first reflective alignment structure 170a can include a metal oxide having a high dielectric constant, such as barium titanate (BaTiO3).

In addition, the dielectric constant of the first reflective alignment structure 170a can be greater than that of the fluid as a medium.

In addition, as the first reflective alignment structure 170a protrudes in the direction of the first electrode layer 154a, the DEP force can be maximized by maximizing the volume occupied by the first semiconductor light emitting device 150A.

Also, the second semiconductor light emitting device 150B can be disposed in the second assembly hole 203b of the second assembly substrate structure 200B.

The second semiconductor light emitting device 150B can include a light emitting structure 152, a passivation layer 156 on the light emitting structure 152, and a second reflective alignment structure 170b disposed in the light emitting structure 152.

The second reflective alignment structure 170b can be disposed at a position overlapping the third protruding electrode 203p and the fourth protruding electrode 204p.

Accordingly, as the second reflective alignment structure 170b is disposed at a position overlapping the third electrode 203 and the fourth electrode 204, the DEP force can be maximized.

In addition, as the second reflective alignment structure 170b protrudes in the direction of the second electrode layer 154b, the DEP force can be maximized by maximizing the volume occupied by the second semiconductor light emitting device 150B.

In addition, as the DEP force applied to the second reflective alignment structure 170b is maximized, when the second semiconductor light emitting device 150B is assembled, the upper and lower sides are reversed to prevent erroneous assembly, and the probability of the normal assembly rate can be significantly improved.

In addition, when the second reflective alignment structure 170b is disposed under the second semiconductor light emitting device 150B As the DEP force is maximized, there is a special technical effect of remarkably improving the alignment accuracy of the first electrode layer 154a and the second electrode layer 154b of the second semiconductor light emitting device 150B, the third electrode 203 serving as an electrode of the panel, and the fourth electrode, the assembly position and assembly direction of the second semiconductor light emitting device 150B are controlled.

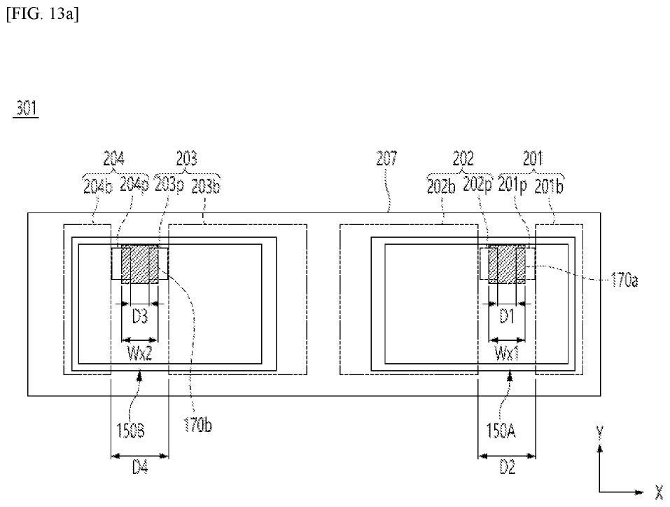

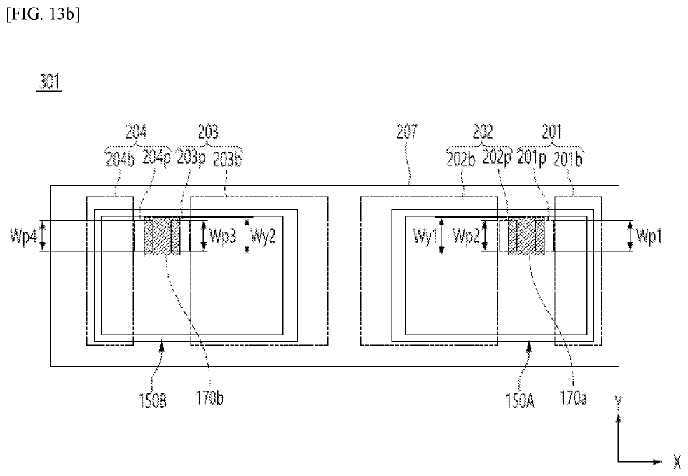

Next, FIGS. 13A and 13B are detailed plan views of the semiconductor light emitting device display 301 according to the first embodiment shown in FIG. 12A.

Referring to FIG. 13A, the first reflective alignment structure 170a can have a first-first width Wx1 in the first axis (X) direction.

A first-first width Wx1 in the first axis (X) direction of the first reflective alignment structure 170a can be greater than a first separation distance D1 between the first protruding electrode 201p and the second protruding electrode 202p.

The first-first width Wx1 in the first axis (X) direction of the first reflective alignment structure 170a can be smaller than a second separation distance D1 between the first electrode body 201b and the second electrode body 202b.

According to the embodiment, a first-first width Wx1 in the first axis (X) direction of the first reflective alignment structure 170a is greater than a first separation distance D1 between the first protruding electrode 201p and the second protruding electrode 202p, as it is designed to be smaller than the second separation distance D1 between the first electrode body 201b and the second electrode body 202b, when AC power is applied to the first electrode 201 and the second electrode 202, a DEP force can be intensively formed between the first protruding electrode 201p and the second protruding electrode 202p.

In addition, by the first reflective alignment structure 170a of the first semiconductor light emitting device 150A is disposed overlapping the first protruding electrode 201p and the second protruding electrode 202p, a strong DEP force can be applied to the first reflective alignment structure 170a.

Also, referring to FIG. 13A, the second reflective alignment structure 170b can have a first-second width Wx2 in the first axis (X) direction.

A first-second width Wx2 in the first axis (X) direction of the second reflective alignment structure 170b can be greater than a third separation distance D3 between the third protruding electrode 203p and the fourth protruding electrode 204p.

A first-second width Wx2 in the first axis (X) direction of the second reflective alignment structure 170b can be smaller than a fourth separation distance D4 between the third electrode body 203b and the fourth electrode body 204b.

According to the embodiment, a first-second width Wx2 in the first axis (X) direction of the second reflective alignment structure 170b is greater than a third separation distance D3 between the third protruding electrode 203p and the fourth protruding electrode 204p, as it is designed to be smaller than the fourth separation distance D4 between the third electrode body 203b and the fourth electrode body 204b, when AC power is applied to the third electrode 203 and the fourth electrode 204, a DEP force can be intensively formed between the third protruding electrode 203p and the fourth protruding electrode 204p.

In addition, by the second reflective alignment structure 170b of the second semiconductor light emitting device 150B is overlapped with the third protruding electrode 203p and the fourth protruding electrode 204p, a strong DEP force can be applied to the second reflective alignment structure 170b.

Next, referring to FIG. 13B, the first reflective alignment structure 170a can have a second-first width Wy1 in the second axis (Y) direction.

A second-first width Wy1 in the second axis (Y) direction of the first reflective alignment structure 170a can be greater than the first protrusion width Wp1 in the second axis (Y) direction of the first protruding electrode 201p.

In addition, the second-first width Wy1 in the second axis (Y) direction of the first reflective alignment structure 170a can be greater than the second protrusion width Wp2 in the second axis (Y) direction of the second protruding electrode 202p.

In the embodiment, the second-first width Wy1 in the second axis (Y) direction of the first reflective alignment structure 170a is greater than the first protruding width Wp1 in the second axis (Y) direction of the first protruding electrode 201p, as the second protruding electrode 202p is designed to be larger than the second protruding width Wp2 in the second axis (Y) direction, a strong DEP force can be applied to the first reflective alignment structure 170a by increasing a probability that the first reflective alignment structure 170a overlaps the first protruding electrode 201p and the second protruding electrode 202p.

Also, referring to FIG. 13B, the second reflective alignment structure 170b can have a second-second second width Wy2 in the second axis Y direction.

A second-second second width Wy2 in the second axis (Y) direction of the second reflective alignment structure 170b can be greater than the third protrusion width Wp3 in the second axis Y direction of the third protruding electrode 203p.

In addition, a second-second second width Wy2 in the second axis (Y) direction of the third reflective alignment structure 170c can be greater than a fourth protrusion width Wp4 in the second axis Y direction of the fourth protruding electrode 204p.

According to the embodiment, a second-second second width Wy2 in the second axis (Y) direction of the second reflective alignment structure 170b is greater than the third protrusion width Wp3 in the second axis (Y) direction of the third protruding electrode 203p, and can be designed to be larger than the fourth protrusion width Wp4 in the second axis (Y) direction of the fourth protruding electrode 204p. Through this, a strong DEP force can be applied to the second reflective alignment structure 170b by increasing the probability that the second reflective alignment structure 170b overlaps the third protruding electrode 203p and the fourth protruding electrode 204p.

Next, FIG. 14A is a detailed plan view of the first semiconductor light emitting device 150A and the second semiconductor light emitting device 150B in the first semiconductor light emitting device display shown in FIG. 11B.

FIG. 14B is a cross-sectional view taken along line C1-C2 of the first semiconductor light emitting device 150A and the second semiconductor light emitting device 150B shown in FIG. 14A.

Also, FIG. 14C is a cross-sectional view taken along line C3-C4 of the first semiconductor light emitting device 150A and the second semiconductor light emitting device 150B shown in FIG. 14A.

Referring to FIGS. 14A to 14C, the first semiconductor light emitting device 150A according to the embodiment can include a light emitting structure 152 including a first conductivity type semiconductor layer 152a, an active layer 152b, a second conductivity type semiconductor layer 152c, a first electrode layer 154a electrically connected to the first conductivity-type semiconductor layer 152a and a second electrode layer 154b electrically connected to the second conductivity type semiconductor layer 152c.

The first semiconductor light emitting device 150A according to the embodiment can include a passivation layer 156 formed on the surface of the light emitting structure 152.

The first semiconductor light emitting device 150A according to the embodiment can include a first reflective alignment structure 170a disposed in a partial region of the first conductivity type semiconductor layer 152a.

The first reflective alignment structure 170a may overlap at least a portion of the first electrode layer 154a or the second electrode layer 154b in upper and lower directions.

For example, the first reflective alignment structure 170a can be disposed to overlap the first electrode layer 154a of the first semiconductor light emitting device 150A.

In the embodiment, the first reflective alignment structure 170a is disposed to overlap the first electrode layer 154a of the first semiconductor light emitting device 150A, since the dielectric constant of the first reflective alignment structure 170a is greater than that of the light emitting structure 152, the DEP force can be concentrated on the first reflective alignment structure 170a.

Accordingly, since the first reflective alignment structure 170a is positioned between the first protruding electrode 201p and the second protruding electrode 202p, there is a special technical effect of serving as an alignment key of the first semiconductor light emitting device 150A.

Also, the surface of the first reflective alignment structure 170a can have roughness (not shown).

Therefore, as the light emitted from the active layer 152b is reflected by the first reflective alignment structure 170a, light extraction efficiency can be improved and the luminance of the display can be improved.

The first reflective alignment structure 170a can include a first reflective alignment body 170a1 and a first reflective protrusion 170a2 protruding from the first reflective alignment body 170a1 toward the first electrode layer 154a.

As the first reflective alignment structure 170a protrudes in the direction of the first electrode layer 154a or the second electrode layer 154b, by maximizing the volume occupied by the first semiconductor light emitting device 150A, the DEP force can be maximized.

Next, the second semiconductor light emitting device 150B can include a second reflective alignment structure 170b disposed in a partial region of the first conductivity-type semiconductor layer 152a and overlapping the second electrode layer 154b.

The second reflective alignment structure 170b can include a second protruding reflective assembly that protrudes in the direction of the second electrode layer 154b.

The second protruding reflective assembly unit can include roughness.

The second reflective alignment structure 170b can include a second reflective alignment body 170b1 and a second reflective protrusion 170b2 protruding from the second reflective alignment body 170b1 toward the second electrode layer 154b.

As the second reflective alignment structure 170b protrudes in the direction of the first electrode layer 154a or the second electrode layer 154b, by maximizing the volume occupied by the second semiconductor light emitting device 150B, the DEP force can be maximized.

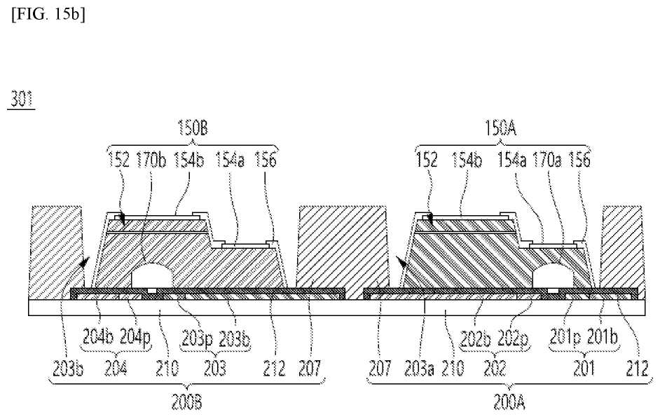

Next, FIGS. 15A and 15B are views illustrating assembly of the semiconductor light emitting device display 301 according to the first embodiment.

Referring to FIGS. 15A and 15B, the first electrode 201 of the first assembly substrate structure 200A of the embodiment includes a first protruding electrode 201p protruding in the direction of the second electrode 202, the second electrode 202 can include a second protruding electrode 202p protruding toward the first electrode 201. The first protruding electrode 201p and the second protruding electrode 202p can be disposed to face each other.

In addition, the third electrode 203 of the second assembly substrate structure 200B of the embodiment includes a third protruding electrode 203p protruding in the direction of the fourth electrode 204, the fourth electrode 204 can include a fourth protruding electrode 204p protruding toward the third electrode 203. The third protruding electrode 203p and the fourth protruding electrode 204p can be disposed to face each other.

Through this, when AC power is applied between the first electrode 201, the second electrode 202, the third electrode 203, and the fourth electrode 204, DEP force is intensively formed between the first protruding electrode 201p and the second protruding electrode 202p and between the third protruding electrode 203p and the fourth protruding electrode 204p, so the first semiconductor light emitting device 150A and the second semiconductor light emitting device 150B can be efficiently assembled.

In addition, the first reflective alignment structure 170a provided in the first semiconductor light emitting device 150A of the embodiment can be disposed at a position overlapping with the first electrode 201 and the second electrode 202 at the same time. Accordingly, the DEP force can be maximized.

In addition, according to the embodiment, as the DEP force applied to the first reflective alignment structure 170a is maximized, the upper and lower sides of the first semiconductor light emitting device 150A are reversed when assembling to prevent mis-assembly and significantly improve the probability of the normal assembly rate.

Also, according to the embodiment, the first reflective alignment structure 170a is disposed to overlap the first electrode layer 154a of the first semiconductor light emitting device 150A, since the dielectric constant of the first reflective alignment structure 170a is greater than that of the light emitting structure 152, the DEP force can be concentrated on the first reflective alignment structure 170a. Accordingly, since the first reflective alignment structure 170a is positioned between the first protruding electrode 201p and the second protruding electrode 202p, there is a special technical effect of serving as an alignment key of the first semiconductor light emitting device 150A.

Also, according to the embodiment, the second reflective alignment structure 170b is disposed to overlap the second electrode layer 154b of the second semiconductor light emitting device 150B, since the dielectric constant of the second reflective alignment structure 170b is greater than that of the light emitting structure 152, the DEP force can be concentrated on the second reflective alignment structure 170b. Accordingly, since the second reflective alignment structure 170b is positioned between the third protruding electrode 203p and the fourth protruding electrode 204p, there is a special technical effect of serving as an alignment key of the first semiconductor light emitting device 150B.

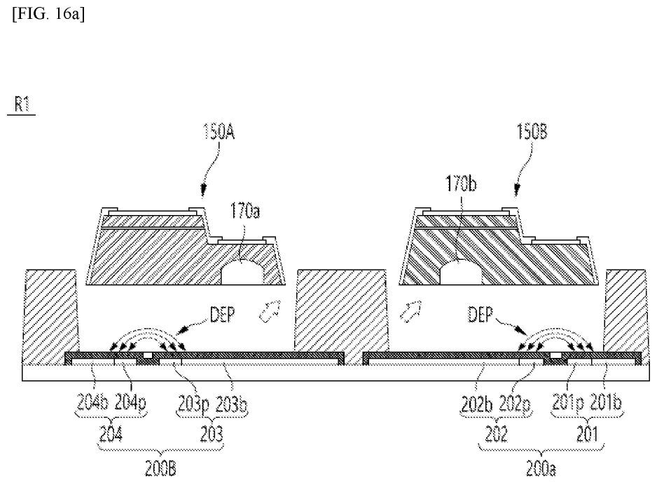

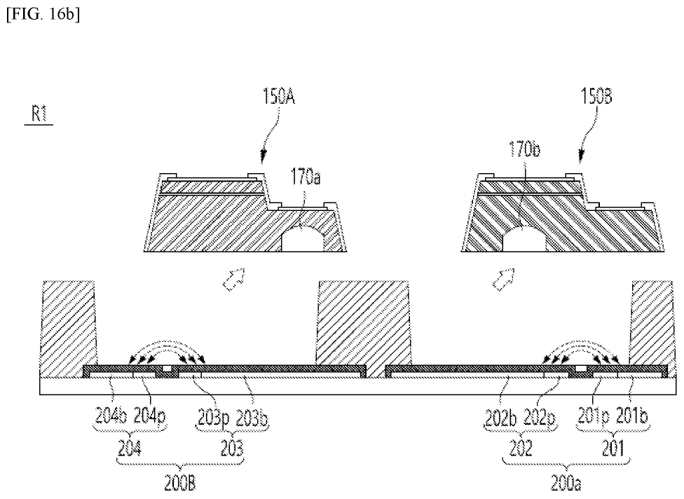

Next, FIGS. 16A and 16B are assembly comparative example (R1) when the first semiconductor light emitting device 150A and the second semiconductor light emitting device 150B according to the embodiment are positioned in the second assembly substrate structure 200B and the first assembly substrate structure 200A, respectively

Referring to FIG. 16A is an exemplary view when the first semiconductor light emitting device 150A is positioned on the second assembly substrate structure 200B in a state in which it is not rotated 180 degrees with respect to FIG. 11B.

Also, it is an exemplary view when the second semiconductor light emitting device 150B is positioned on the first assembly substrate structure 200A in a state in which it is not rotated 180 degrees with reference to FIG. 11B.

Referring to FIG. 16A, since the first reflective alignment structure 170a of the first semiconductor light emitting device 150A is disposed at a position separated from the third protruding electrode 203p and the fourth protruding electrode 204p, it is not properly affected by the DEP force. Accordingly, as shown in FIG. 16B, the first semiconductor light emitting device 150A can be separated from the second assembly substrate structure 200B.

Also, referring to FIG. 16A, since the second reflective alignment structure 170b of the second semiconductor light emitting device 150B is disposed at a position separated from the first protruding electrode 201p and the second protruding electrode 202p, it is not properly affected by the DEP force. Accordingly, as shown in FIG. 16B, the second semiconductor light emitting device 150B can be separated from the first assembly substrate structure 200A.

On the other hand, when the first semiconductor light emitting device 150A is positioned in the second assembly substrate structure 200B in a state rotated 180 degrees with reference to FIG. 11B, since the first reflective alignment structure 170a itself is disposed to be spaced apart from the third protruding electrode 203p and the fourth protruding electrode 204p by a considerable distance. Also, since the DEP force does not affect the first reflective alignment structure 170a and the first semiconductor light emitting device 150A cannot be assembled, it will be separated from the second assembly hole 203b.

On the other hand, when the second semiconductor light emitting device 150B is positioned in the first assembly substrate structure 200A in a state rotated 180 degrees with reference to FIG. 11B, since the second reflective alignment structure 170b itself is disposed to be spaced apart from the first protruding electrode 201p and the second protruding electrode 202p by a considerable distance. Also, since the DEP force does not affect the second reflective alignment structure 170b and the second semiconductor light emitting device 150B cannot be assembled, it will be separated from the first assembly hole 203a.

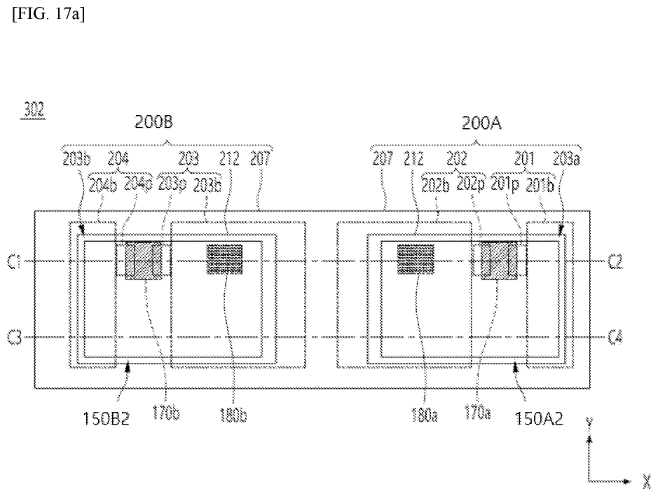

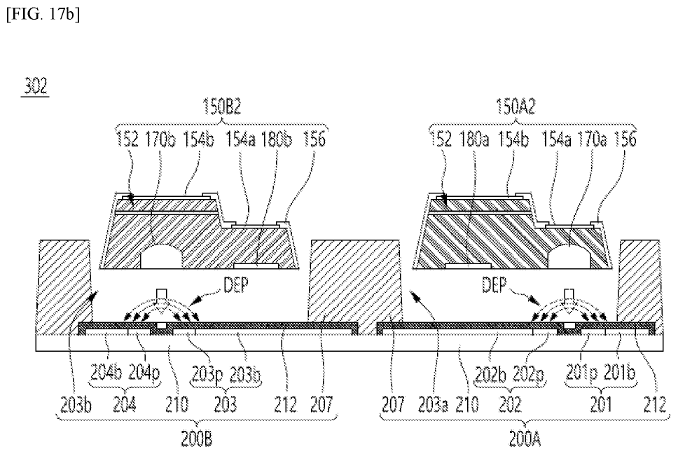

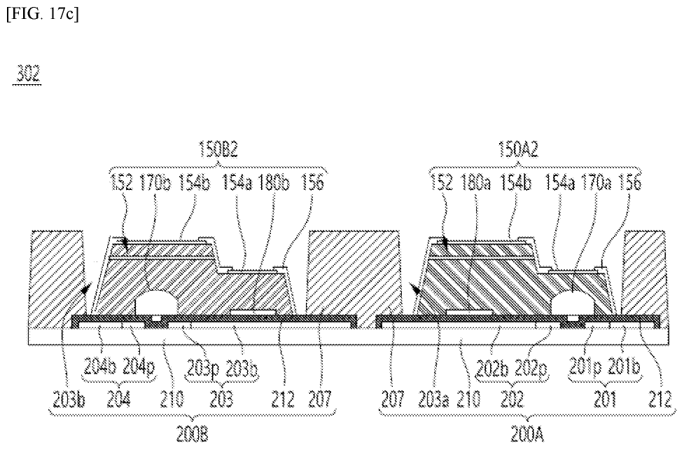

Next, FIG. 17A is a plan view of the second semiconductor light emitting device display 302 according to the embodiment.

Also, FIGS. 17B and 17C are assembly views based on a cross-sectional view taken along line C1-C2 of the second semiconductor light emitting device display 302 shown in FIG. 17A.

The second semiconductor light emitting device display 302 may employ the technical features of the first semiconductor light emitting device display 301 described above, hereinafter, the main characteristics of the second semiconductor light emitting device display 302 will be described.

Referring to FIG. 17A, the second semiconductor light emitting device display 302 can include a first-second semiconductor light emitting device 150A2 and a second-second semiconductor light emitting device 150B2.

The first-second semiconductor light emitting device 150A2 and the second-second semiconductor light emitting device 150B2 can be assembled to the first assembly substrate structure 200A and the second assembly substrate structure 200B, respectively.

The first-second semiconductor light emitting device 150A2 can include a first repulsive structure 180a in the light emitting structure.

The first repulsive structure 180a can be disposed to be spaced apart from the first reflective alignment structure 170a.

The first repulsive structure 180a can be disposed to be spaced apart from the first reflective alignment structure 170a on a line horizontal to the X-axis.

In addition, the second-second semiconductor light emitting device 150B2 can include a second repulsive structure 180b in the light emitting structure.

The second repulsive structure 180b can be disposed to be spaced apart from the second reflective alignment structure 170b. The second repulsive structure 180b can be disposed to be spaced apart from the second reflective alignment structure 170b on a line horizontal to the X-axis.

The first repulsive structure 180a can include a material in which a negative DPE force is generated. In addition, the second repulsive structure 180b can include a material generating a negative DPE force.

For example, in the Clausius-Mossotti factor (CM factor) that determines the direction of the DEP force, the first repulsive structure 180a and the second repulsive structure 180b can be formed of a material having a dielectric constant smaller than that of the fluid which is a medium.

For example, the first repulsive structure 180a and the second repulsive structure 180b can include any one or more of Ge, ceramic, quartz, and glass, but are not limited thereto.

When a DEP force is applied between the first protruding electrode 201p and the second protruding electrode 202p, a positive DEP force may act on the first reflective alignment structure 170a.

On the other hand, when a DEP force is applied between the first protruding electrode 201p and the second protruding electrode 202p, a negative DEP force can be applied to the first repulsive structure 180a.

Also, when a DEP force is applied between the third protruding electrode 203p and the fourth protruding electrode 204p, a positive DEP force may act on the second reflective alignment structure 170b. On the other hand, when a DEP force is applied between the third protruding electrode 203p and the fourth protruding electrode 204p, a negative DEP force can be applied to the second repulsive structure 180b.

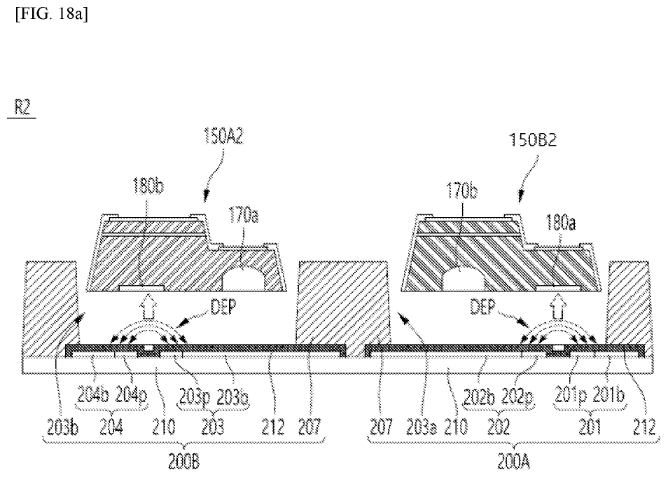

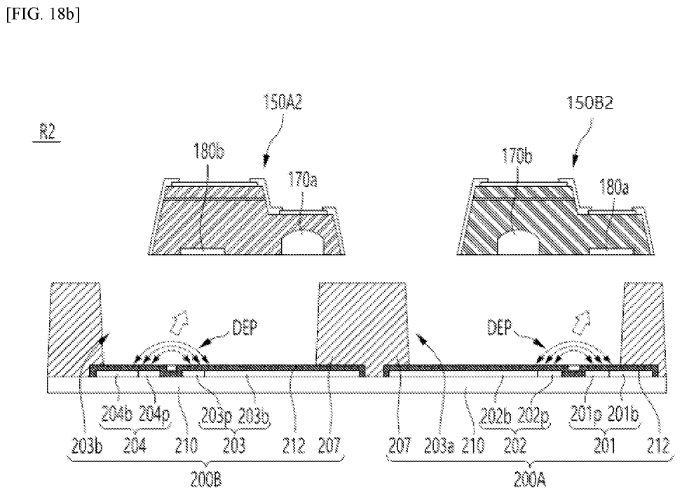

FIGS. 18A and 18B are a second assembly comparative example R2 in the case where the second-first semiconductor light emitting device 150A2 and second-second semiconductor light emitting device 150B2 according to the embodiment are positioned in the second assembly substrate structure 200B and first assembly substrate structure 200A, respectively.

FIG. 18A is an exemplary view when the first-second semiconductor light emitting device 150A2 is positioned in the second assembly substrate structure 200B in a state in which it is not rotated 180 degrees with respect to FIG. 17A.

It is also an exemplary view when the second-second semiconductor light emitting device 150B2 is positioned in the first assembly substrate structure 200A in a state in which it is not rotated 180 degrees with reference to FIG. 17A.

Referring to FIG. 18A, the first repulsive structure 180a of the first-second semiconductor light emitting device 150A2 is disposed at a position overlapping the third protruding electrode 203p and the fourth protruding electrode 204p and is affected by negative DEP force. Accordingly, as shown in FIG. 18B, there is a special technical effect that the first-second semiconductor light emitting device 150A2 is effectively separated from the second assembly substrate structure 200B.

Also, referring to FIG. 18A, the second repulsive structure 180b of the second-second semiconductor light emitting device 150B2 is disposed at a position overlapping the first protruding electrode 201p and the second protruding electrode 202p and is affected by a negative DEP force. Accordingly, as shown in FIG. 18B, the second-second semiconductor light emitting device 150B2 has a special technical effect of effectively leaving the first assembly substrate structure 200A.

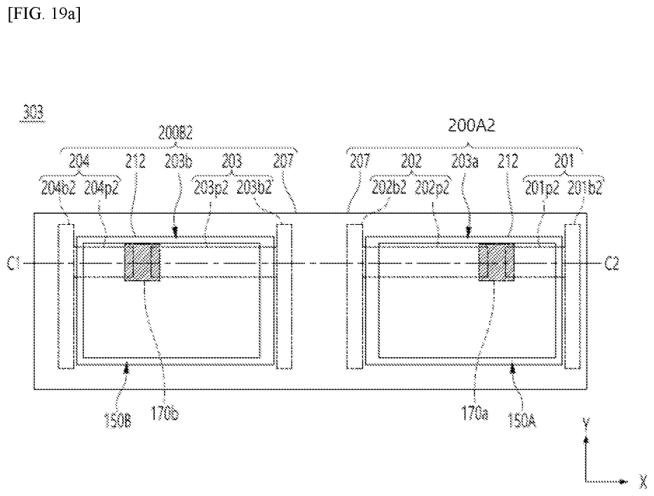

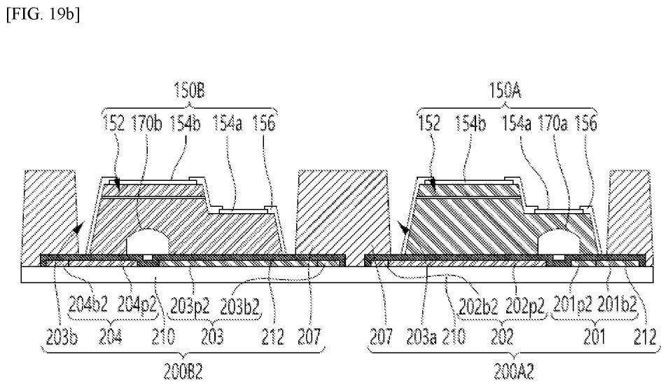

FIG. 19A is a plan view of a third semiconductor light emitting device display 303 according to an embodiment.

FIG. 19B is a cross-sectional view taken along line C1-C2 of the third semiconductor light emitting device display 303 shown in FIG. 19A.

The third semiconductor light emitting device display 303 may employ the technical features of the first and second semiconductor light emitting device displays 301 and 302 described above,

Hereinafter, the main characteristics of the third semiconductor light emitting device display 303 will be mainly described.

The third semiconductor light emitting device display 303 can include a first semiconductor light emitting device 150A and a second semiconductor light emitting device 150B.

The first semiconductor light emitting device 150A and the second semiconductor light emitting device 150B can be assembled into a first-second assembly substrate structure 200A2 and a second-second assembly substrate structure 200B2, respectively.

The first electrode 201 of the first-second assembly substrate structure 200A2 can include a first-second electrode body 201b2 and a first-second protruding electrode 201p2 protruding from the first-second electrode body 201b2 toward the second electrode 202.

In addition, the second electrode 202 of the first-second assembly substrate structure 200A2 can include a second-second electrode body 202b2 and a second-second protrusion electrode 202p2 protruding from the second-second electrode body 202b2 toward the first electrode 201.

The first-second electrode body 201b2 may not overlap the upper and lower portions of the first semiconductor light emitting device 150A. Also, the second-second electrode body 202b2 may not overlap the first semiconductor light emitting device 150A vertically.

Accordingly, there is a special technical effect that the DEP force applied to the first semiconductor light emitting device 150A can be intensively generated between the first-second protrusion electrode 201p2 and the second-second protrusion electrode 202p2 that are disposed to face each other and are adjacent to each other.

In addition, the third electrode 203 of the second-second assembly substrate structure 200B2 can include a third-second electrode body 203b2 and a third-second protruding electrode 203p2 protruding from the third-second electrode body 203b2 toward the fourth electrode 204.

In addition, the fourth electrode 204 of the second-second assembly substrate structure 200B2 can include a fourth-second electrode body 204b2 and a fourth-second protruding electrode 204p2 protruding from the fourth-second electrode body 204b2 toward the third electrode 203.

The third-second electrode body 203b2 may not overlap the second semiconductor light emitting device 150B vertically. The fourth-second electrode body 204b2 may also not overlap the second semiconductor light emitting device 150B vertically.

Accordingly, there is a special technical effect that the DEP force applied to the second semiconductor light emitting device 150B can be intensively generated between the third-second protrusion electrode 203p2 and the fourth-second protrusion electrode 204p2 that are disposed to face each other and are adjacent to each other.

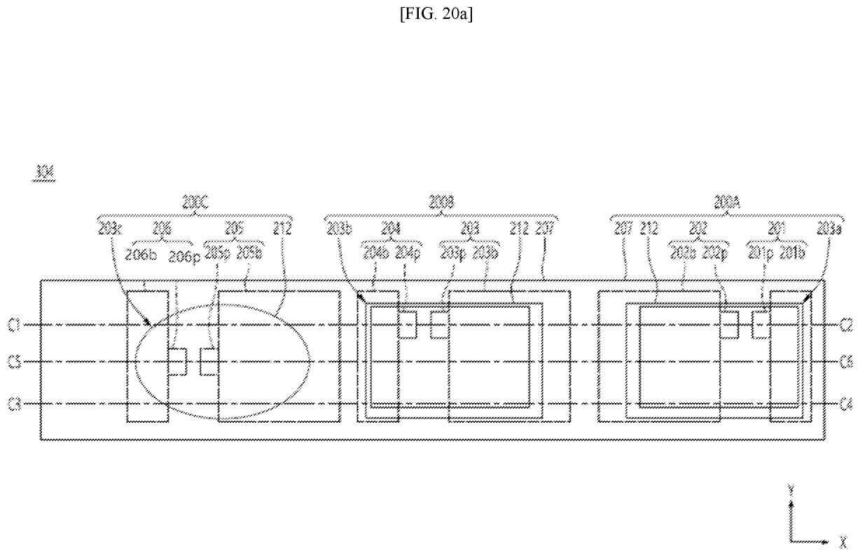

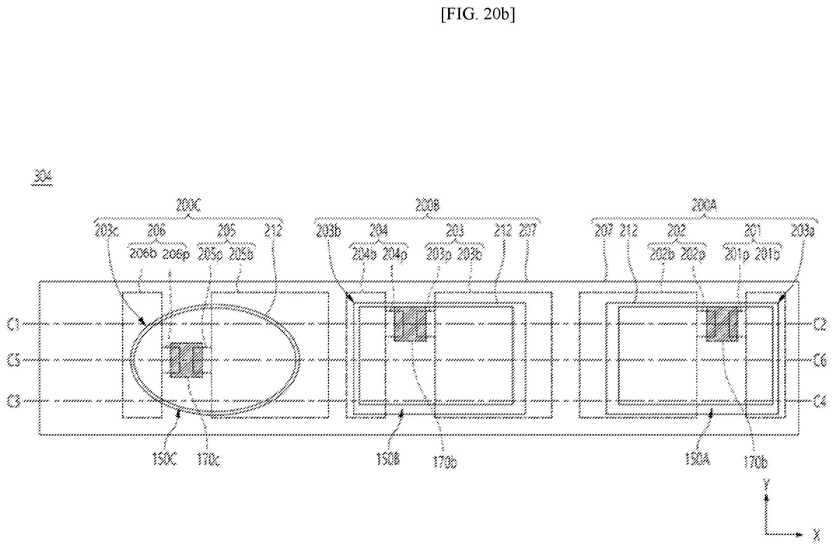

Next, FIGS. 20A and 20B are plan views of the fourth semiconductor light emitting device display 304 according to the embodiment.

The fourth semiconductor light emitting device display 304 may employ the technical features of the first to third semiconductor light emitting device displays 301, 302, 303, hereinafter, the main characteristics of the fourth semiconductor light emitting device display 304 will be mainly described.

The fourth semiconductor light emitting device display 304 can include a first semiconductor light emitting device 150A, a second semiconductor light emitting device 150B, and a third semiconductor light emitting device 150C.

The first semiconductor light emitting device 150A, the second semiconductor light emitting device 150B, and the third semiconductor light emitting device 150C can be assembled to the first assembly substrate structure 200A, the second assembly substrate structure 200B, and the third assembly substrate structure 200C, respectively. And the third assembly substrate structure 200C can include a third assembly hole 203c.

Horizontal cross-sections of the first semiconductor light emitting device 150A and the second semiconductor light emitting device 150B can be polygonal, for example, a rectangle, but are not limited thereto. A horizontal cross section of the third semiconductor light emitting device 150C can have a circular or elliptical shape, and thus is not limited thereto.

In addition, the horizontal cross section of the first semiconductor light emitting device 150A and the second semiconductor light emitting device 150B can be circular or elliptical, and the horizontal cross section of the third semiconductor light emitting device 150C can be polygonal, but is not limited thereto.

Referring to FIGS. 20A and 20B, horizontal cross sections of the first assembling hole 203a and the second assembling hole 203b can be polygonal, for example, a rectangle, to correspond to the horizontal surfaces of the first semiconductor light emitting device 150A and the second semiconductor light emitting device 150B, but is not limited thereto.

In addition, the horizontal cross section of the third assembly hole 203c can be circular or oval to correspond to the horizontal cross section of the third semiconductor light emitting device 150C, but is not limited thereto.

On the other hand, the horizontal cross-sections of the first assembling hole 203a and the second assembling hole 203b can be circular or oval, and the horizontal cross-section of the third assembling hole 203c can be polygonal, but is not limited thereto.

In the embodiment, the third assembly substrate structure 200C can include a fifth electrode 205 and a sixth electrode 206.

The fifth electrode 205 of the third assembly substrate structure 200C can include a fifth electrode body 205b and a fifth protruding electrode 205p protruding from the fifth electrode body 205b toward the sixth electrode 206.

In the third assembly substrate structure 200C, the sixth electrode 206 can include a sixth electrode body 206b and a sixth protruding electrode 206p protruding from the sixth electrode body 206b toward the fifth electrode 205.

The fifth protruding electrode 205p and the sixth protruding electrode 206p can be disposed to face each other based on line C5-C6.

The line C5-C6 can be disposed between the line C1-C2 and the line C3-C4, and can be a center line in the second axis (Y) direction of a predetermined substrate.

The first protruding electrode 201p and the second protruding electrode 202p can be disposed to face each other based on line C1-C2. Also, the third protruding electrode 203p and the fourth protruding electrode 204p can be disposed to face each other based on a line C1-C2.

The third semiconductor light emitting device 150C can include a third reflective alignment structure 170c at a position overlapping the fifth protruding electrode 205p and the sixth protruding electrode 206p.

Accordingly, according to the embodiment, in the LED chip for a display panel, the first semiconductor light emitting device 150A and the second semiconductor light emitting device 150B have a technical effect of increasing the assembly selectivity between chips while maintaining the same shape.

Further, according to the embodiment, in the LED chip for a display panel, the third semiconductor light emitting device 150C can have different shapes from the first semiconductor light emitting device 150A and the second semiconductor light emitting device 150B. As the position of the third reflective alignment structure 170c is disposed on a different horizontal line from the horizontal line of the first reflective alignment structure 170a and the second reflective alignment structure 170b of the first semiconductor light emitting device 150A and the second semiconductor light emitting device 150B, there is a special technical effect that can significantly increase the assembly selectivity between chips by precisely controlling the location of the DEP force for each color.

For example, the third semiconductor light emitting device 150C is not only difficult to assemble in the first assembly hole 203a or the second assembly hole 203b due to the difference in horizontal cross section, the position of the third reflective alignment structure 170c is not affected by the DEP force in the positions of the first assembly hole 203a and the second assembly hole 203b. Accordingly, there is a special technical effect that can significantly increase the assembly selectivity between chips by organically combining the shape of the assembly hole, control of the cross-sectional shape of the light emitting device, the position of the protruding electrode, and the arrangement relationship of the first reflective alignment structure.

The above detailed description should not be construed as restrictive in all respects and should be considered as exemplary. The scope of the embodiments should be determined by a reasonable interpretation of the appended claims, and all modifications within the equivalent scope of the embodiments are included in the scope of the embodiments.

The embodiment can be employed in the field of display for displaying images or information.

The embodiment can be applied to a display field for displaying images or information using a semiconductor light emitting device.

The embodiment can be employed in a display field for displaying images or information using a micro-level or nano-level semiconductor light emitting device.

What is claimed is:

1. A substrate structure for a display panel, the substrate structure comprising:
a first electrode and a second electrode spaced apart from each other on a substrate;
an insulating layer disposed on the first and second electrodes; and
a first barrier wall disposed on the insulating layer and including a first assembly hole,
wherein the first electrode comprises a first electrode body and a first protruding electrode protruding from the first electrode body toward the second electrode, and
the second electrode comprises a second electrode body and a second protruding electrode protruding from the second electrode body toward the first electrode.

2. The substrate structure for a display panel according to claim 1, wherein the first protruding electrode and the second protruding electrode are disposed to face each other.

3. A semiconductor light emitting device disposed on a substrate structure for a display panel, the substrate structure including a first electrode and a second electrode, the semiconductor light emitting device comprising:
a light emitting structure;
a passivation layer on the light emitting structure; and
a first reflective alignment structure disposed in the light emitting structure.

4. The semiconductor light emitting device for a display panel according to claim 3, wherein the first reflective alignment structure is formed of a metal layer or a high-k metal oxide.

5. The semiconductor light emitting device for a display panel according to claim 3, wherein a dielectric constant of the first reflective alignment structure is greater than a dielectric constant of the light emitting structure.

6. A display device comprising:
a first electrode and a second electrode spaced apart from each other on a substrate;
an insulating layer disposed on the first and second electrodes;
a first barrier wall disposed on the insulating layer and comprising a first assembly hole; and
a semiconductor light emitting device disposed in the first assembly hole of the first barrier wall,
wherein the semiconductor light emitting device comprises:
a light emitting structure;
a passivation layer on the light emitting structure; and
a first reflective alignment structure disposed in the light emitting structure.

7. The display device according to claim 6, wherein the first electrode comprises a first electrode body and a first protruding electrode protruding from the first electrode body toward the second electrode, and
wherein the second electrode comprises a second electrode body and a second protruding electrode protruding from the second electrode body toward the first electrode.

8. The display device according to claim 7, wherein the first protruding electrode and the second protruding electrode are disposed to face each other.

9. The display device according to claim 6, wherein the first reflective alignment structure is formed of a metal layer or a high-k metal oxide.

10. The display device according to claim 6, wherein a dielectric constant of the first reflective alignment structure is greater than a dielectric constant of the light emitting structure.

11. The display device according to claim 7, wherein the first reflective alignment structure is disposed at a position overlapping the first protruding electrode and the second protruding electrode.

12. The display device according to claim 7, wherein the first reflective alignment structure protrudes in an upper direction of the light emitting structure.

13. The display device according to claim 7, wherein a second axial-directional second-first width of the first reflective alignment structure is greater than a second axial-directional first protrusion width of the first protruding electrode, and is greater than a second axial-directional second protrusion width of the second protruding electrode.

14. The display device according to claim 13, wherein the light emitting structure comprises a first conductivity type semiconductor layer, an active layer and a second conductivity type semiconductor layer,
wherein the display device further comprises a first electrode layer electrically connected to the first conductivity type semiconductor layer and a second electrode layer electrically connected to the second conductivity type semiconductor layer, and
wherein the first reflective alignment structure overlaps at least a portion of the first electrode layer or the second electrode layer in upper and lower directions.

15. The display device according to claim 7, wherein a surface of the first reflective alignment structure comprises a roughness.

16. The display device according to claim 7, wherein the first reflective alignment structure comprises a first reflective alignment body and a first reflective protrusion protruding from the first reflective alignment body toward the first electrode layer.

17. The display device according to claim 7, wherein the semiconductor light emitting device comprises a repulsive structure disposed spaced apart from the first reflective alignment structure in the light emitting structure.

18. The display device according to claim 6, wherein the second electrode includes a second-second electrode body and a second-second protrusion electrode protruding from the second-second electrode body toward the first electrode, and
wherein the second-second electrode body does not overlap the upper and lower portions of the semiconductor light emitting device.

19. The display device according to claim 6, wherein the first electrode includes a first-second electrode body and a first-second protruding electrode protruding from the first-second electrode body toward the second electrode.

20. The display device according to claim 14, wherein the first reflective alignment structure is imbedded in the second conductivity type semiconductor layer.
